(19) United States
(12) Patent Application Publication
(10) Pub. No.: US 2026/0005087 A1
(43) Pub. Date: Jan. 1, 2026

(54) ELECTRONIC DEVICE

(71) Applicant: Rohm Co., Ltd., Kyoto-shi (JP)

(72) Inventors: Ryohei UMENO, Kyoto-shi (JP); Tomomi SATO, Kyoto-shi (JP); Tomohira KIKUCHI, Kyoto-shi (JP)

(21) Appl. No.: 19/322,030

(22) Filed: Sep. 8, 2025

Related U.S. Application Data
(63) Continuation of application No. PCT/JP2024/007012, filed on Feb. 27, 2024.

(30) Foreign Application Priority Data
Mar. 15, 2023 (JP) 2023-040763

(51) Int. Cl. H01L 23/31; H01L 23/495

(52) U.S. Cl. CPC H01L 23/3107; H01L 23/49541; H01L 23/49575

(57) ABSTRACT

An electronic device includes a conductive support, an electronic element on the conductive support, and a sealing resin covering the electronic element and the conductive support. The sealing resin has a first resin side surface facing in a first direction perpendicular to a thickness direction of the conductive support. The first resin side surface has a first gate mark. The conductive support includes a first region nearest to the first gate mark in the first direction. The first region is positioned inward of the first gate mark in a second direction perpendicular to the thickness direction and the first direction. The first gate mark has a first dimension in the thickness direction. The first gate mark and the first region are spaced in the first direction by a first distance. The ratio of the first distance to the first dimension is less than or equal to 500%.

### TECHNICAL FIELD

The present disclosure relates to electronic devices.

### BACKGROUND ART

Electronic devices include various types, among which semiconductor devices fabricated using lead frames are conventionally known. JP-A-2022-55599 discloses an example of such a semiconductor device. The semiconductor device disclosed in JP-A-2022-55599 includes a conductive support member, a semiconductor element, and a sealing resin. The conductive support member includes a die pad and a plurality of terminals. The semiconductor element is mounted on the die pad. The terminals are disposed around the die pad. The sealing resin collectively covers the die pad, the semiconductor element, and a portion of each terminal. The sealing resin is formed by transfer molding. The process of forming the sealing resin includes placing the lead frame into a mold, injecting molten resin into the mold cavity, and hardening the resin. FIG. 12 of JP-A-2022-55599 shows an example in which resin is injected from the central location in the lateral direction of the figure. The resin injecting site is positioned away from the portions of the lead frame that will later form terminals (the conductive support member) to ensure unobstructed resin flow. However, if molten resin is injected at high speed, air may be entrapped during the injection process and remain as voids (pinholes) near the injection site. This may result in incomplete filling in the sealing resin.

### BRIEF DESCRIPTION OF THE DRAWINGS

FIG. 1 is a plan view of an electronic device according to a first embodiment of the present disclosure.

FIG. 2 is a plan view corresponding to FIG. 1, in which a sealing resin is depicted as transparent.

FIG. 3 is a front view of the electronic device according to the first embodiment of the present disclosure.

FIG. 4 is a left-side view of the electronic device according to the first embodiment of the present disclosure.

FIG. 5 is a rear view of the electronic device according to the first embodiment of the present disclosure.

FIG. 6 is a right-side view of the electronic device according to the first embodiment of the present disclosure.

FIG. 7 is a sectional view taken along line VII-VII in FIG. 2.

FIG. 8 is a sectional view taken along line VIII-VIII in FIG. 2.

FIG. 9 is an enlarged view of a portion of FIG. 2.

FIG. 10 is a plan view illustrating a manufacturing step of the electronic device according to the first embodiment of the present disclosure.

FIG. 11 is a plan view illustrating a manufacturing step of the electronic device according to the first embodiment of the present disclosure.

FIG. 12 is a plan view illustrating a manufacturing step of the electronic device according to the first embodiment of the present disclosure.

FIG. 13 is a plan view of an electronic device according to a first variation of the first embodiment, in which a sealing resin is depicted as transparent.

FIG. 14 is an enlarged view of a portion of FIG. 13.

FIG. 15 is a plan view of an electronic device according to a second embodiment of the present disclosure.

FIG. 16 is a plan view corresponding to FIG. 15, in which a sealing resin is depicted as transparent.

FIG. 17 is a front view of the electronic device according to the second embodiment of the present disclosure.

FIG. 18 is a left-side view of the electronic device according to the second embodiment of the present disclosure.

FIG. 19 is a rear view of the electronic device according to the second embodiment of the present disclosure.

FIG. 20 is a right-side view of the electronic device according to the second embodiment of the present disclosure.

FIG. 21 is a sectional view taken along line XXI-XXI in FIG. 16.

FIG. 22 is a sectional view taken along line XXI-XXI in FIG. 16.

FIG. 23 is a circuit diagram of the electronic device according to the second embodiment of the present disclosure.

FIG. 24 is a plan view of an electronic device according to a first variation of the second embodiment, in which a sealing resin is depicted as transparent.

### DETAILED DESCRIPTION OF EMBODIMENTS

The following specifically describes preferred embodiments of the present disclosure with reference to the drawings.

In the present disclosure, the terms such as "first", "second", "third", and so on are used only as labels and not to imply an order of the items referred to by the terms.

In the present disclosure, the expressions "An object A is formed in an object B", and "An object A is formed on an object B" imply the situation where, unless otherwise specifically noted, "the object A is formed directly in or on the object B", and "the object A is formed in or on the object B, with something else interposed between the object A and the object B ." Likewise, the expressions "An object A is arranged in an object B", and "An object A is arranged on an object B" imply the situation where, unless otherwise specifically noted, "the object A is arranged directly in or on the object B", and "the object A is arranged in or on the object B, with something else interposed between the object A and the object B." Further, the expression "An object A is positioned on an object B" implies the situation where, unless otherwise specifically noted, "the object A is positioned on the object B, in contact with the object B", and "the object A is positioned on the object B, with something else interposed between the object A and the object B." The expression "An object A overlaps with an object B as viewed in a certain direction" implies the situation where, unless otherwise specifically noted, "the object A overlaps with the entirety of the object B", and "the object A overlaps with a portion of the object B." In the present disclosure, the expression "A surface A faces in a direction B (or a first side or a second side in the direction B) is not limited, unless otherwise specifically noted, to the situation where the surface A forms an angle of 900 with the direction B but includes the situation where the surface A is inclined relative to the direction B.

### First Embodiment:

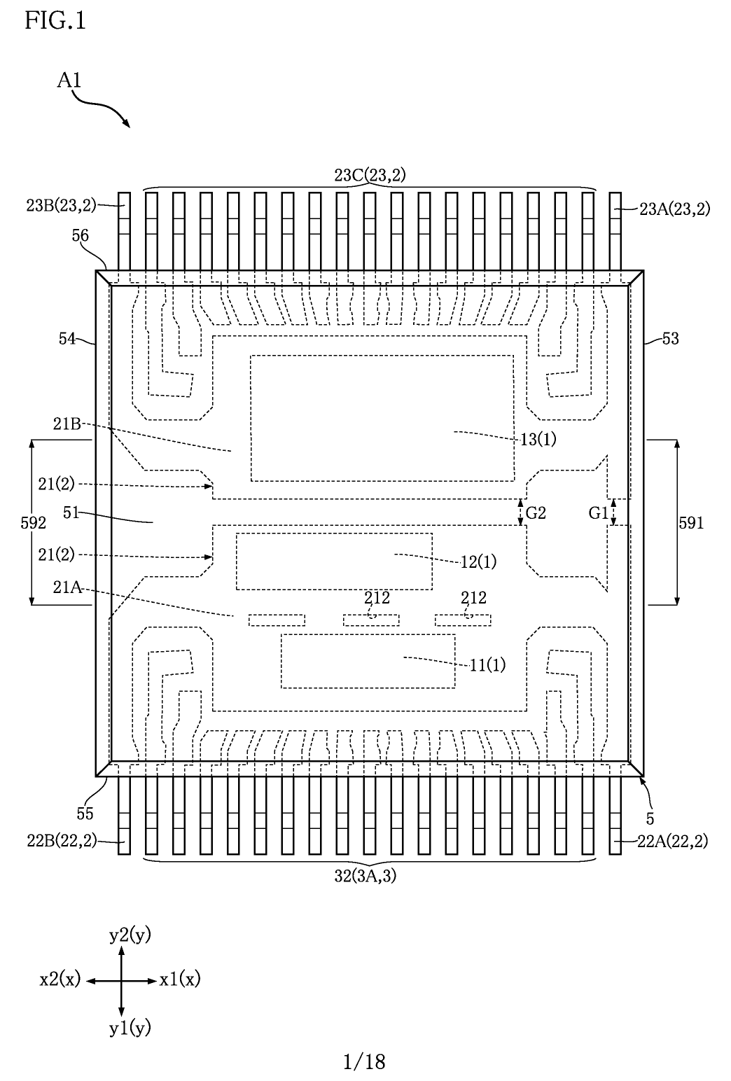

With reference to FIGS. 1 to 9 the following describes an electronic device according to a first embodiment of the present disclosure. The electronic device Al of the present embodiment includes a plurality of electronic elements 1, a conductive support member 2, a plurality of wires 31 to 34, and a sealing resin 5. The conductive support member 2 includes a die pad portion 21, a plurality of first lead terminals 22, and a plurality of second lead terminals 23. Although the usage and other details of the electronic device Al are not particularly limited, it may be configured for surface mounting on a wiring board of an inverter device used in an electric vehicle or a hybrid vehicle. The electronic device Al is packaged in a SOP (small outline package). The packaging of the electronic device A1, however, is not limited to an SOP.

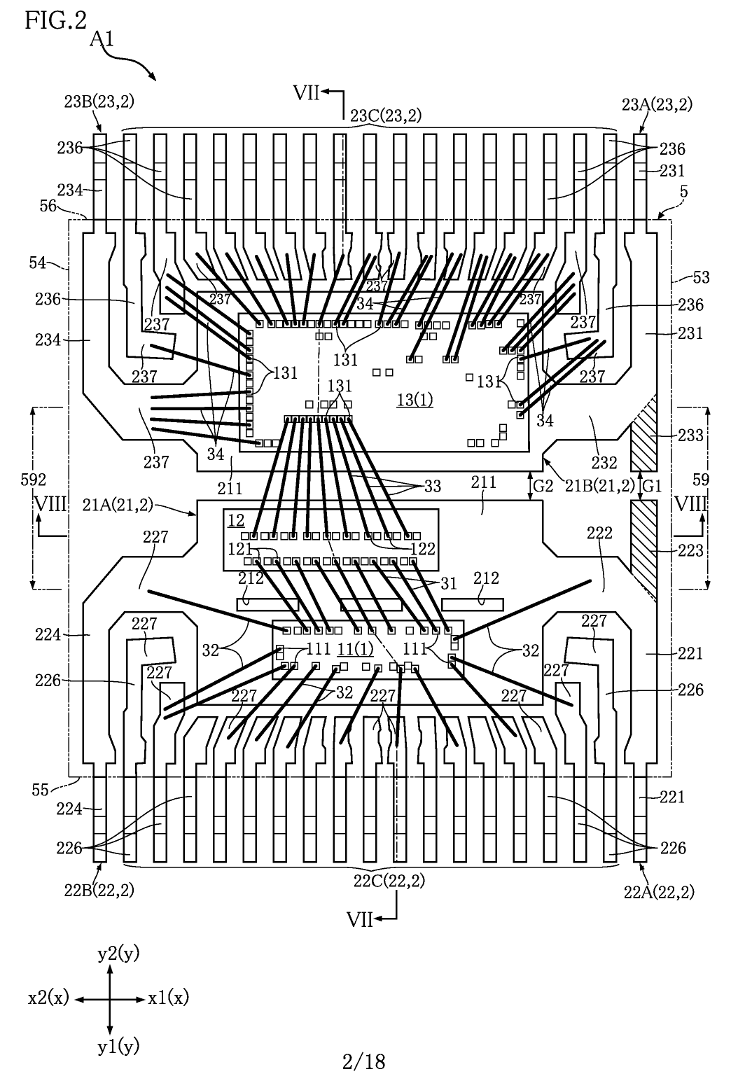

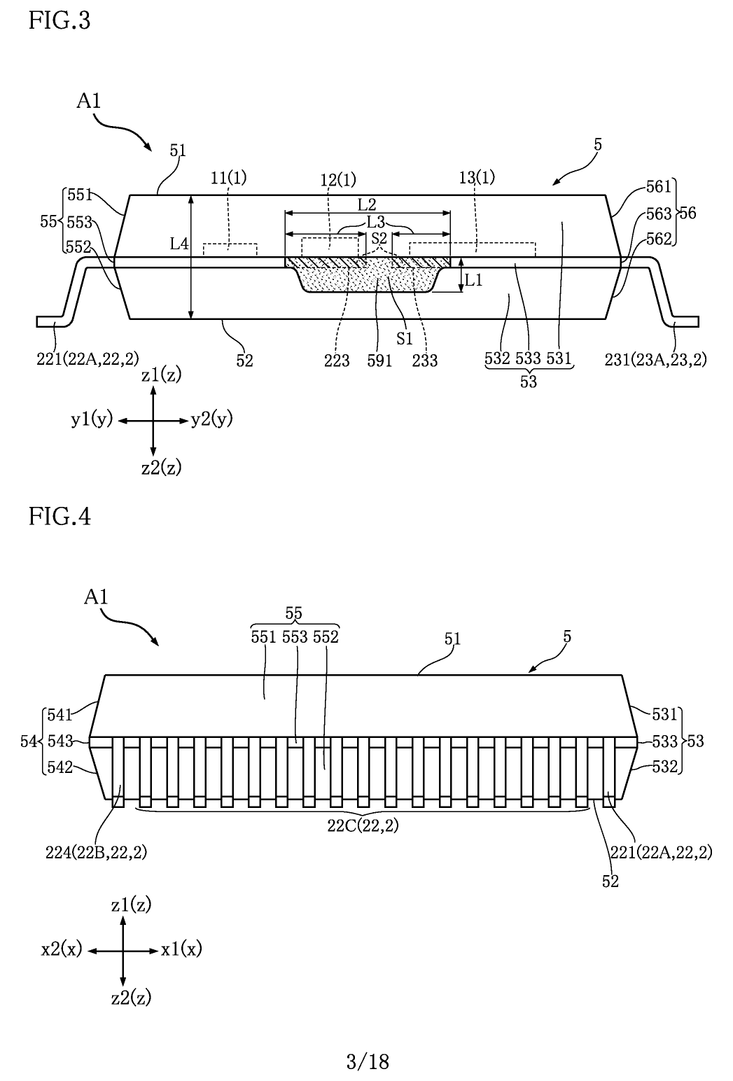

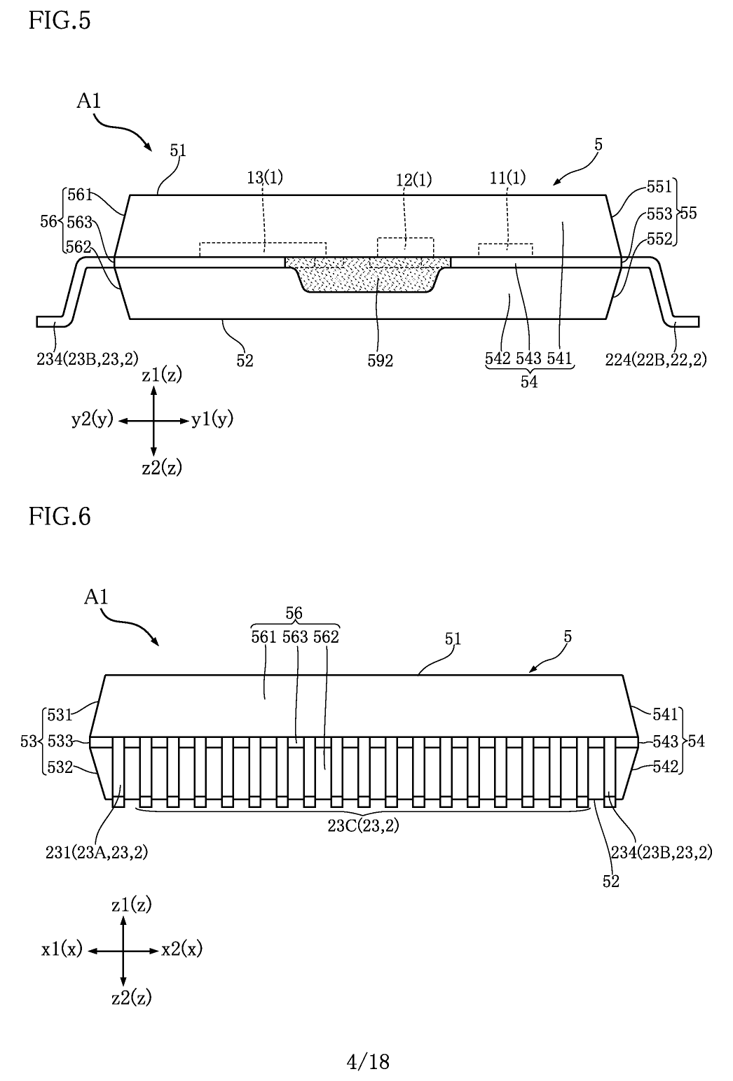

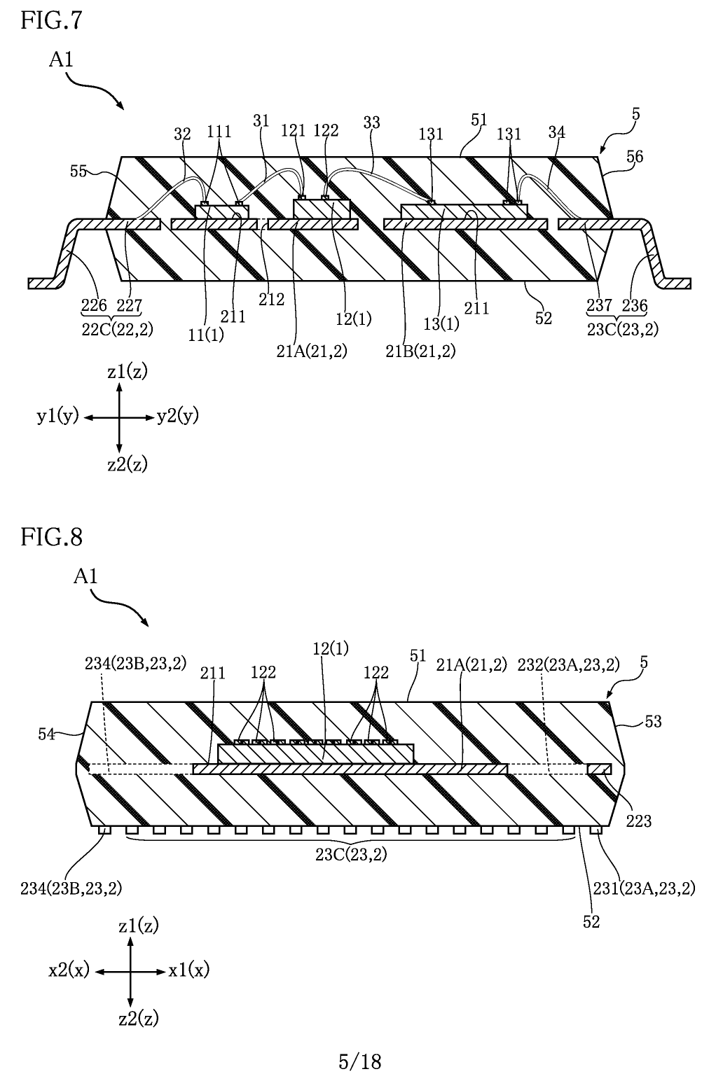

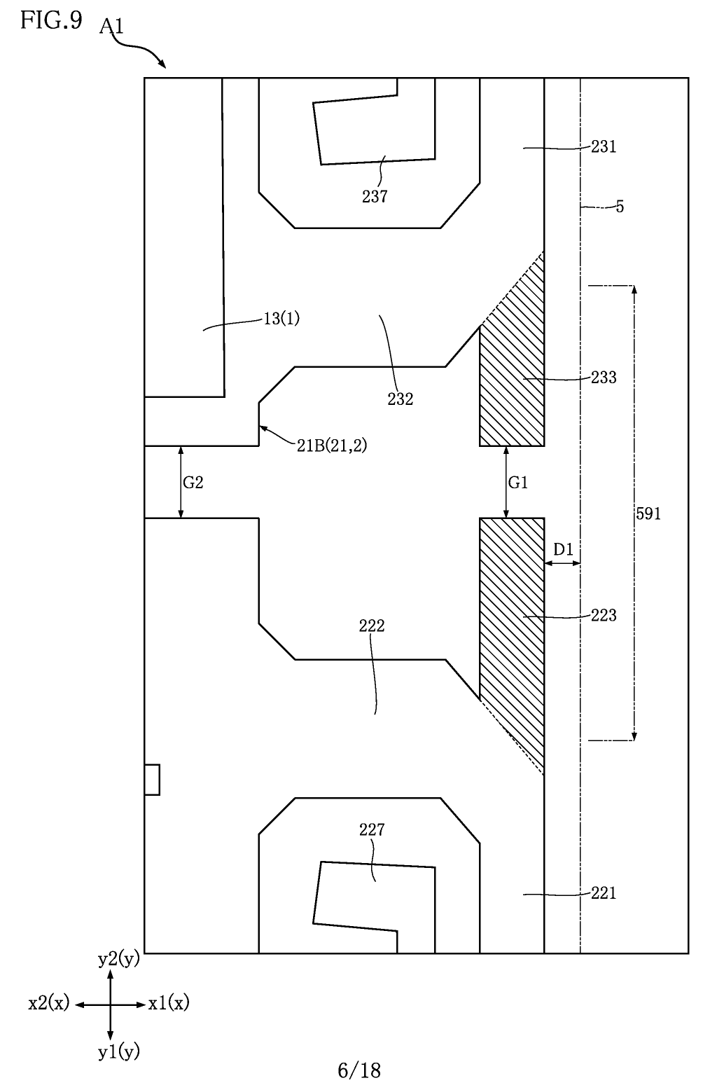

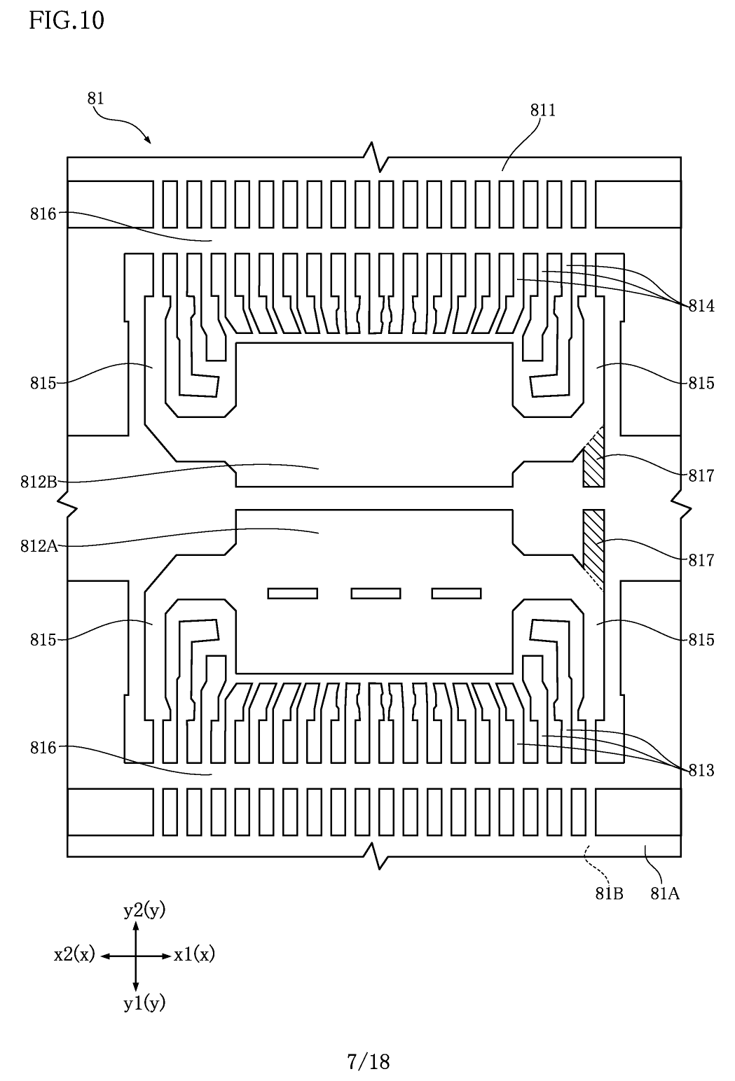

FIGS. 1 and 2 are plan views of the electronic device A1. FIG. 3 is a front view of the electronic device A1. FIG. 4 is a left-side view of the electronic device A1. FIG. 5 is a rear view of the electronic device A1. FIG. 6 is a right-side view of the electronic device A1. FIG. 7 is a sectional view taken along line VII-VII in FIG. 2. FIG. 8 is a sectional view taken along line VIII- VIII in FIG. 2. FIG. 9 is an enlarged view of a portion of FIG. 2. For ease of understanding, FIG. 2 depicts the sealing resin 5 as transparent. In FIG. 2, the outline of the sealing resin 5 is indicated by imaginary lines (dash-double-dot lines).

In the description of the present disclosure, reference is made to three mutually perpendicular directions as needed. For example, in the description of the electronic device A1, the thickness direction of the die pad portion 21 (the conductive support member 2) is defined as the "thickness direction z". A direction perpendicular to the thickness direction z (the lateral direction in FIG. 1) is defined as the "first direction x". The direction perpendicular to both the thickness direction z (the vertical direction in FIG. 1) and the first direction x is defined as the "second direction y." As shown in FIGS. 1 and 2, the electronic device Al is rectangular (or substantially rectangular) as viewed in the thickness direction z (in plan view).

As shown in FIGS. 1 and 2, the plurality of electronic elements 1 of the present embodiment 13, and the insulating element 12 are each formed as a discrete element. As viewed in the thickness direction z, the first semiconductor element 11, the second semiconductor element 13, and the insulating element 12 are each have a rectangular shape elongated in the first direction x.

The first semiconductor element 11 is a controller (a control element) of the gate driver for driving a switching element, such as IGBT or MOSFET. The first semiconductor element 11 include a first semiconductor element 11, an insulating element 12, and a second semiconductor element 13. The first semiconductor element 11, the second semiconductor element 13, and the insulating element 12 are components that serve as the functional core of the electronic device A1. In the electronic device A1, the first semiconductor element 11, the second semiconductor element includes a circuit that converts a control signal received from an ECU or the like into a PWM control signal, a transmission circuit that sends the PWM control signal to the second semiconductor element 13, and a receiving circuit that receives an electrical signal from the second semiconductor element 13. The first semiconductor element 11 is an example of the "first electronic element" in the present disclosure.

The second semiconductor element 13 is a gate driver (a driving element) that drives a switching element. The second semiconductor element 13 includes a receiving circuit that receives the PWM control signal, a circuit that drives the switching element in response to the PWM control signal, and a transmission circuit that sends an electrical signal to the first semiconductor element 11. Examples of the electrical signal include an output signal of a temperature sensor disposed near a motor. The second semiconductor element 13 is an example of the "second electronic element" in the present disclosure.

The insulating element 12 is a component that transmits a PWM control signal and other electrical signals while maintaining electrical insulation. In the electronic device A1, the insulating element 12 is of an inductive type. One example of the inductive-type insulating element 12 is an isolation transformer. The isolation transformer transmits an electrical signal by inductively coupling two inductors (coils) while ensuring electrical isolation. The insulating element 12 includes a substrate mad of silicon. The inductors made of copper are formed on the substrate. The inductors include a transmitting-side inductor and a receiving-side inductor that are stacked one on top of the other in the thickness direction z. Between the transmitting-side and receiving-side inductors, a dielectric layer made of materials such as silicon dioxide (SiO2) is interposed. The dielectric layer electrically isolates the transmitting-side inductor and the receiving-side inductor. In other examples, the insulating element 12 may be of a capacitive type.

Examples of the capacity-type insulating element 12 include a capacitor. Alternatively, the insulating element 12 may be a photocoupler.

In the electronic device A1, the second semiconductor element 13 requires a higher supply voltage than the first semiconductor element 11. This results in a large potential difference between the first semiconductor element 11 and the second semiconductor element 13. Thus, the electronic device Al includes the insulating element 12 to electrically isolate a first circuit, which includes the first semiconductor element 11 as a component, and a second circuit, which includes the second semiconductor element 13 as a component. The first circuit and the second circuit have a relatively different potential. In the electronic device A1, the second circuit is at a higher potential than the first circuit. With this being a situation, the insulating element 12 transmits signals between the first circuit and the second circuit. For example, in an inverter device for an electric vehicle or a hybrid vehicle, the voltage applied to the ground of the first semiconductor element 11 is approximately 0 V, whereas the voltage applied to the ground of the second semiconductor element 13 can transiently reach 600 V or higher.

As shown in FIGS. 2 and 7, the first semiconductor element 11 is provided with a plurality of electrodes 111 disposed on its upper surface (the surface facing the same side as the later- described mounting surface 211 of the die pad portion 21). The electrodes 111 are electrically connected to the circuit formed in the first semiconductor element 11. Similarly, the second semiconductor element 13 is provided with a plurality of electrodes 131 disposed on its upper surface (the surface facing the same side as the mounting surface 211). The electrodes 131 are electrically connected to the circuit formed in the second semiconductor element 13.

As shown in FIGS. 2 and 7, the insulating element 12 is positioned between the first semiconductor element 11 and the second semiconductor element 13 in the second direction y.

The insulating element 12 is provided with a plurality of first electrodes 121 and a plurality of second electrodes 122 disposed on its upper surface (the surface facing the same side as the mounting surface 211). The first electrodes 121 and the second electrodes 122 are each electrically connected to the transmitting-side inductor or the receiving-side inductor. The first electrodes 121 are arranged along the first direction x at positions closer to the first semiconductor element 11 than to the second semiconductor element 13 in the second direction y. The second electrodes 122 are arranged along the first direction x at positions closer to the second semiconductor element 13 than to the first semiconductor element 11 in the second direction y.

In the electronic device A1, the conductive support member 2 is a component that forms a element 12, and the second semiconductor element 13 are mounted. As shown in FIGS. 1 and 2, the conductive support member 2 includes the die pad portion 21, the first lead terminals 22, and the second lead terminals 23. The first semiconductor element 11, the second semiconductor element 13, and the insulating element 12 are mounted on the die pad portion 21. In the present embodiment, the die pad portion 21 includes a first die pad 21A and a second die pad 21B. The first die pad 21A is positioned on the yl side in the second direction y, whereas the second die pad 21B is positioned on the y2 side in the second direction y. The first die pad 21A and the second die pad 21B are spaced apart from each other in the second direction y. Thus, an inter-pad gap G2 is provided between the first die pad 3 and the second die pad 4 in the second direction y. In plan view, the inter-pad gap G2 extends in the first direction x. In the electronic device A1, the first semiconductor element 11 and the insulating element 12 are mounted on the first die pad 21A, and the second semiconductor element 13 on the second die pad 21B.

The die pad portion 21 (the first die pad 21A and the second die pad 21B) is covered with conduction path from the first semiconductor element 11, the second semiconductor element 13, and the insulating element 12 to the wiring board of an inverter device. The conductive support member 2 is made of an alloy containing copper (Cu), for example. The conductive support member 2 is fabricated from a lead frame 81, which will be described later. The conductive support member 2 is a component on which the first semiconductor element 11, the insulating the sealing resin 5. The die pad portion 21 (each of the first die pad 21A and the second die pad 21B) has a mounting surface 211 facing the zl side in the thickness direction z. The first semiconductor element 11 and the insulating element 12 are mounted on the mounting surface 211 of the first die pad 21A. The second semiconductor element 13 is mounted on the mounting surface 211 of the second die pad 21B. The first semiconductor element 11, the second semiconductor element 13, and the insulating element 12 are each bonded to the mounting surface 211 of a corresponding one of the first die pad 21A and the second die pad 21B via a conductive bonding material (e.g., solder or metal paste), which is not shown in the figures. The first die pad 21A and the second die pad 21B (the die pad portion 21) have a thickness of 100 pm or greater and 300 pm or less, for example.

As shown in FIGS. 2 and 7, the first die pad 21A is formed with a plurality of through-holes 212. Each through-hole 212 penetrates the first die pad 21A in the thickness direction z and extends in the first direction x. As viewed in the thickness direction z, at least one of the through- holes 212 is positioned between the first semiconductor element 11 and the insulating element 12. The through-holes 212 are arranged along the first direction x.

The first lead terminals 22 are bonded to the wiring board of a device such as an inverter, to provide a conduction path between the electronic device Al and the wiring board. At least one of the first lead terminals 22 is electrically connected to the first semiconductor element 11. As shown in FIGS. 1, 2, and 4, the first lead terminals 22 are arranged along the first direction x with spacing between them. The first lead terminals 22 protrude from the sealing resin 5 (the third resin side surface 55, which will be described later) toward the yl side in the second direction y and thus are exposed. The plurality of first lead terminals 22 include a first-side first terminal 22A, a second-side first terminal 22B, and a plurality of intermediate first terminals 22C.

The first-side first terminal 22A is the outermost one on the xl side in the first direction x, among the plurality of first lead terminals 22. As shown in FIG. 2, the first-side first terminal 22A includes a first lead portion 221, a first pad portion 222, and a first extending portion 223.

The first lead portion 221 is positioned on the xl side in the first direction x with respect to the first die pad 21A (the die pad portion 21) and extends in the second direction y. The first lead portion 221 includes a portion exposed from the sealing resin 5 and a portion covered with the sealing resin 5. As shown in FIG. 3, the exposed portion of the first lead portion 221 is bent into a gull-wing shape. Additionally, the exposed portion of the first lead portion 221 may be coated. The plating layer is made of alloys, such as solder, that contain tin (Sn) and covers the portion exposed from the sealing resin 5. The plating layer enhances solder adhesion to the exposed portion when the electronic device Al is surface-mounted to the wiring board of an inverter device by soldering, and also protects the exposed portion from erosion caused by solder bonding.

The first pad portion 222 extends from the end of the first lead portion 221 on the y2 side in the second direction y toward the x2 side in the first direction x. The end of the first pad portion 222 on the x2 side in the first direction x is connected to the first die pad 21A. The upper surface (the surface facing the zl side in the thickness direction z) of the first pad portion 222 may be coated with a plating layer. The plating layer may be made of metals, such as silver (Ag), and covers the upper surface of the first pad portion 222. The plating layer enhances the bonding strength of wires 32, which will be described later, and also protects the lead frame 81 (described later) form impact during the bonding process of wires 32. The entire surface of the first pad portion 222 is covered with the sealing resin 5. The first pad portion 222 is flat (or substantially flat).

The first extending portion 223 is connected to the end of the first lead portion 221 on the y2 side in the second direction y, and extends toward the y2 side in the second direction y. In the illustrated example, the first extending portion 223 generally has a rectangular shape elongated in the second direction y. In FIGS. 2 and 9, the first extending portion 223 is shown with hatching.

The first extending portion 223 will be described later in detail.

The second-side first terminal 22B is the outermost one on the x2 side in the first direction x, among the plurality of first lead terminals 22. As shown in FIG. 2, the second-side first terminal 22B includes a lead portion 224 and a pad portion 225.

The lead portion 224 is positioned on the x2 side in the first direction x with respect to the resin 5. As shown in FIG. 5, the exposed portion of the lead portion 224 is bent into a gull-wing shape. Similarly to the first lead portion 221, the exposed portion of the lead portion 224 may be coated with a plating layer (e.g., Sn-containing alloys, such as solder).

The pad portion 225 is connected to the end of the lead portion 224 on the y2 side in the second direction y, and extends toward the xl side in the first direction x. The end of the pad first die pad 21A (the die pad portion 21) and extends in the second direction y. The lead portion 224 includes a portion exposed from the sealing resin 5 and a portion covered with the sealing portion 225 on the xl side in the first direction x is connected to the first die pad 21A. Similarly to the upper surface of the first pad portion 222, the upper surface (the surface facing the zl side in the thickness direction z) of the pad portion 225 may be coated with a plating layer (e.g., metals, such as Ag). The entire surface of the pad portion 225 is covered with the sealing resin 5. The pad portion 225 is flat (or substantially flat).

As shown in FIGS. 2 and 4, the intermediate first terminals 22C are positioned between the first-side first terminal 22A and the second-side first terminal 22B. As shown in FIG. 2, each intermediate first terminal 22C includes a lead portion 226 and a pad portion 227.

The lead portion 226 extends in the second direction y. The lead portion 226 includes a portion exposed from the sealing resin 5 and a portion covered with the sealing resin 5. As shown in FIG. 7, the exposed portion of the lead portion 226 is bent into a gull-wing shape. Similarly to the first lead portion 221, the exposed portion of the lead portion 226 may be coated with a plating layer (e.g., Sn-containing alloys, such as solder).

The pad portion 227 is connected to the end of the lead portion 226 on the y2 side in the second direction y. Similarly to the upper surface of the first pad portion 222, the upper surface (the surface facing the zl side in the thickness direction z) of the pad portion 227 may be coated with a plating layer (e.g., metals, such as Ag). The entire surface of the pad portion 227 is covered with the sealing resin 5. The pad portion 227 is flat (or substantially flat).

The second lead terminals 23 are bonded to the wiring board of a device such as an inverter, to provide a conduction path between the electronic device Al and the wiring board. At least one of the second lead terminals 23 is electrically connected to the second semiconductor element 13. As shown in FIGS. 1, 2, and 6, the second lead terminals 23 are arranged along the first direction x with spacing between them. The second lead terminals 23 protrude from the sealing resin 5 (the fourth resin side surface 56, which will be described later) toward the y2 side in the second direction y and thus are exposed. The plurality of second lead terminals 23 include a first- side second terminal 23A, a second-side second terminal 23B, and a plurality of intermediate second terminals 23C.

The first-side second terminal 23A is the outermost one on the xl side in the first direction x, among the plurality of second lead terminals 23. As shown in FIG. 2, the first-side second terminal 23A includes a second lead portion 231, a second pad portion 232, and a second extending portion 233.

The second lead portion 231 is positioned on the xl side in the first direction x with respect to the second die pad 21B (the die pad portion 21) and extends in the second direction y. The second lead portion 231 includes a portion exposed from the sealing resin 5 and a portion covered with the sealing resin 5. As shown in FIG. 3, the exposed portion of the second lead portion 231 is bent into a gull-wing shape. Similarly to the first lead portion 221, the exposed portion of the second lead portion 231 may be coated with a plating layer (e.g., Sn-containing alloys, such as solder).

The second pad portion 232 is connected to the end of the second lead portion 231 on the yl side in the second direction y, and extends toward the x2 side in the first direction x. The end of the second pad portion 232 on the x2 side in the first direction x is connected to the second die pad 21B. Similarly to the upper surface of the first pad portion 222, the upper surface (the surface facing the zl side in the thickness direction z) of the second pad portion 232 may be coated with a plating layer (e.g., metals, such as Ag). The entire surface of the second pad portion 232 is covered with the sealing resin 5. The second pad portion 232 is flat (or substantially flat).

The second extending portion 233 is connected to the end of the second lead portion 231 on the yl side in the second direction y, and extends toward the yl side in the second direction y.

In the illustrated example, the second extending portion 233 generally has a rectangular shape elongated in the second direction y. In FIGS. 2 and 9, the second extending portion 233 is shown with hatching. An inter-terminal gap G1 is provided between the first extending portion 223 (the first-side first terminal 22A) and the second extending portion 233 (the first-side second terminal 23A) in the second direction y. As shown in FIGS. 2 and 3, the inter-terminal gap G1 overlaps with the inter-pad gap G2 as viewed in the first direction x. The second extending portion 233 will be described later in detail.

The second-side second terminal 23B is the outermost one on the x2 side in the first direction x, among the plurality of second lead terminals 23. As shown in FIG. 2, the second-side second terminal 23B includes a lead portion 234 and a pad portion 235.

The lead portion 234 is positioned on the x2 side in the first direction x with respect to the second die pad 21B (the die pad portion 21) and extends in the second direction y. The lead portion 234 includes a portion exposed from the sealing resin 5 and a portion covered with the sealing resin 5. As shown in FIG. 5, the exposed portion of the lead portion 234 is bent into a gull-wing shape. Similarly to the first lead portion 221, the exposed portion of the lead portion 234 may be coated with a plating layer (e.g., Sn-containing alloys, such as solder).

The pad portion 235 is connected to the end of the lead portion 234 on the yl side in the second direction y, and extends toward the xl side in the first direction x. The end of the pad portion 235 on the xl side in the first direction x is connected to the second die pad 21B.

Similarly to the upper surface of the first pad portion 222, the upper surface (the surface facing the zl side in the thickness direction z) of the pad portion 235 may be coated with a plating layer (e.g., metals, such as Ag). The entire surface of the pad portion 235 is covered with the sealing resin 5. The pad portion 235 is flat (or substantially flat).

As shown in FIGS. 2 and 6, the intermediate second terminals 23C are positioned between the first-side second terminal 23A and the second-side second terminal 23B. As shown in FIG. 2, each intermediate second terminal 23C includes a lead portion 236 and a pad portion 237.

The lead portion 236 extends in the second direction y. The lead portion 236 includes a portion exposed from the sealing resin 5 and a portion covered with the sealing resin 5. As shown in FIG. 7, the exposed portion of the lead portion 236 is bent into a gull-wing shape. Similarly to the first lead portion 221, the exposed portion of the lead portion 236 may be coated with a plating layer (e.g., Sn-containing alloys, such as solder).

The pad portion 237 is connected to the end of the lead portion 236 on the yl side in the second direction y. Similarly to the upper surface of the first pad portion 222, the upper surface (the surface facing the zl side in the thickness direction z) of the pad portion 237 may be coated with a plating layer (e.g., metals, such as Ag). The entire surface of the pad portion 237 is covered with the sealing resin 5. The pad portion 237 is flat (or substantially flat).

The wires 31 to 34, together with the die pad portion 21 (the first die pad 21A and the second die pad 21B), the first lead terminals 22, and the second lead terminals 23, form conduction paths for the first semiconductor element 11, the second semiconductor element 13, and the insulating element 12 to perform predetermined functions. The composition of the wires 31 to 34 includes gold (Au), for example. In other examples, the composition of the wires may include copper or aluminum (Al).

As shown in FIGS. 2 and 7, each wire 31 is connected to one of the first electrodes 121 of the insulating element 12 and also to one of the electrodes 111 of the first semiconductor element 11. Thus, the first semiconductor element 11 and the insulating element 12 are electrically connected to each other. The wires 31 are arranged along the first direction x.

As shown in FIGS. 2 and 7, each wire 32 is connected to one of the electrodes 111 of the first semiconductor element 11 and also to one of the following pad portions: the first pad portion 222 of the first-side first terminal 22A, the pad portion 225 of the second-side first terminal 22B, or the pad portion 227 of one of the intermediate first terminals 22C. Thus, at least one of the first-side first terminal 22A, the second-side first terminal 22B, and the intermediate first terminals 22C is electrically connected to the first semiconductor element 11.

As shown in FIGS. 2 and 7, each wire 33 is connected to one of the second electrodes 122 of the insulating element 12 and also to one of the electrodes 131 of the second semiconductor element 13. Thus, the second semiconductor element 13 and the insulating element 12 are electrically connected to each other. The wires 33 are arranged along the first direction x. In the electronic device A1, the wires 33 extend across the gap between the first die pad 21A and the second die pad 21B.

As shown in FIGS. 2 and 7, each wire 34 is connected to one of the electrodes 131 of the second semiconductor element 13 and also to one of the following pad portions: the pad portion 235 of the second-side second terminal 23B, or the pad portion 237 of one of the intermediate second terminals 23C. Thus, at least one of the second-side second terminal 23B and the intermediate second terminals 23C is electrically connected to the second semiconductor element 13.

As shown in FIGS. 1 and 2, the sealing resin 5 covers the first semiconductor element 11, the second semiconductor element 13, the insulating element 12, the die pad portion 21 (the first die pad 21A and the second die pad 21B), a portion of each first lead terminal 22, and a portion of each second lead terminal 23. As shown in FIG. 7, the sealing resin 5 also covers the wires 31 to 34. The sealing resin 5 is electrically insulating. The sealing resin 5 electrically isolates the first die pad 21A and the second die pad 21B from each other. The sealing resin 5 is made of a material including a black epoxy resin. As viewed in the thickness direction z, the sealing resin 5 is rectangular.

As shown in FIGS. 3 to 6, the sealing resin 5 has a resin obverse surface 51, a resin reverse surface 52, a first resin side surface 53, a second resin side surface 54, a third resin side surface 55, and a fourth resin side surface 56.

As shown in FIGS. 3 to 6, the resin obverse surface 51 and the resin reverse surface 52 are spaced apart from each other in the thickness direction z. The resin obverse surface 51 and the resin reverse surface 52 face away from each other in the thickness direction z. The resin obverse surface 51 faces the zl side in the thickness direction z, and the resin reverse surface 52 faces the z2 in the thickness direction z. The resin obverse surface 51 and the resin reverse surface 52 are each flat (or substantially flat).

As shown in FIGS. 3 to 6, the first resin side surface 53, the second resin side surface 54, the third resin side surface 55, and the fourth resin side surface 56 are each connected to the resin obverse surface 51 and the resin reverse surface 52, and are each positioned between the resin obverse surface 51 and the resin reverse surface 52 in the thickness direction z. As shown in Figs. 1, 4, and 6, the first resin side surface 53 is positioned on the xl side in the first direction x and faces the xl side in the first direction x. The second resin side surface 54 is positioned on the x2 side in the first direction x and faces the x2 side in the first direction x. The third resin side surface 55 and the fourth resin side surface 56 are spaced apart from each other in the second direction y and are each connected to the first resin side surface 53 and the second resin side surface 54. As shown in FIGS. 1, 3 and 5, the third resin side surface 55 is positioned on the yl side in the second direction y and faces the yl side in the second direction y. A portion of each first lead terminal 22 protrudes from the third resin side surface 55. The fourth resin side surface 56 is positioned on the y2 side in the second direction y and faces the y2 side in the second direction y.

A portion of each second lead terminal 23 protrudes from the fourth resin side surface 56.

As shown in FIGS. 3, 4, and 6, the first resin side surface 53 includes a first upper section 531, a first lower section 532, and a first intermediate section 533. The first upper section 531 is connected to the resin obverse surface 51 at the zl-side end in the thickness direction z and to the first intermediate section 533 at the z2-side end in the thickness direction z. The first upper section 531 is inclined relative to the resin obverse surface 51. The first lower section 532 is connected to the resin reverse surface 52 at the z2-side end in the thickness direction z and to the first intermediate section 533 at the zl-side end in the thickness direction z. The first lower section 532 is inclined relative to the resin reverse surface 52. The first intermediate section 533 is connected to the first upper section 531 at the zl-side end in the thickness direction z and to the first lower section 532 at the z2-side end in the thickness direction z. The in-plane direction of the first intermediate section 533 is parallel to both the thickness direction z and the second direction y. As viewed in the thickness direction z, the first intermediate section 533 lies outside the resin obverse surface 51 and the resin reverse surface 52.

As shown in FIG. 3, the first resin side surface 53 has a first gate mark 591. The surface of the first gate mark 591 is rougher than other regions of the first resin side surface 53. The first gate mark 591 is formed during the manufacturing process of the electronic device A1, which will be described later, resulting from cutting the sealing resin 5 at a first gate 891 in the step of forming the sealing resin 5. In the electronic device A1, the first gate mark 591 includes a region positioned in the first lower section 532 and a region positioned in the first intermediate section 533. The first gate mark 591 is positioned in the middle of the first resin side surface 53 in the second direction y.

As shown in FIGS. 2 and 9, the first extending portion 223 of the first-side first terminal 22A includes a region that lies inward of the first gate mark 591 in the second direction y, as viewed in the thickness direction z. The second extending portion 233 of the first-side second terminal 23A includes a region that lies inward of the first gate mark 591 in the second direction y, as viewed in the thickness direction z. The first extending portion 223 and the second extending portion 233 are the nearest portions of the conductive support member 2 to the first gate mark 591 in the first direction x. In each of the first extending portion 223 and the second extending portion 233, the region that lies inward of the first gate mark 591 in the second direction y, as viewed in the thickness direction z, is an example of the "first region" recited in the present disclosure. In FIG. 3, the regions of the first extending portion 223 and the second extending portion 233 that lie inward of the first gate mark 591 in the second direction y (the first regions) are shown with hatching.

In the present embodiment, as shown in FIG. 3 and as viewed the in first direction x, the region of the first extending portion 223 that lies inward of the first gate mark 591 in the second direction y overlaps with the first gate mark 591. As viewed in first direction x, the region of the second extending portion 233 that lies inward of the first gate mark 591 in the second direction y overlaps with the first gate mark 591. In the illustrated example, the entire regions of the first extending portion 223 and the second extending portion 233 that lie inward of the first gate mark 591 in the second direction y overlap with the first gate mark 591 as viewed in the first direction x.

In the present embodiment, the following holds between the first gate mark 591 and the region of each of the first extending portion 223 and the second extending portion 233 that lies inward of the first gate mark 591 in the second direction y (the first region). In the present embodiment, a first distance D1 represents the distance in the first direction x between the first gate mark 591 and the region of each of the first extending portion 223 and the second extending portion 233 that lies inward of the first gate mark 591 in the second direction y, and a first dimension L1 represents the length of the first gate mark 591 in the thickness direction z (see Figs. 3 and 9). The ratio of the first distance D1 to the first dimension L1 is within the range greater than 0% and less than or equal to 500%, and preferably within the range of 40% to 200%. The specific value of the first distance D1 is, for example, greater than 0 mm and less than or equal to 2.4 mm, and more preferably ranges from 0.21 mm to 1.0 mm. In the illustrated example of the present embodiment, the first distance D1 is about 0.35 mm. In the illustrated example, the first dimension L1 is about 0.5 mm.

When a second dimension L2 represents the length of the first gate mark 591 in the second direction y, the second dimension L2 and the first distance D1 are related such that one becomes shorter as the other becomes longer (see FIG. 3). The second dimension L2 ranges from 1.0 mm to 5.0 mm, for example, and the product of the second dimension L2 and the first distance D1 ranges from 0.21 mm2 to 5.0 mm2. In the illustrated example of the present embodiment, the second dimension L2 is about 3.0 mm.

As viewed in the first direction x, an area S1 represents the area of the first gate mark 591, and an area S2 represents the area where the region of each of the first extending portion 223 and the second extending portion 233 that lies inward of the first gate mark 591 in the second direction y (the first region) overlaps with the first gate mark 591. The ratio of the area S2 to the area S1 is greater than 0% and less than or equal to 50% (see FIG. 3). In the illustrated example of the present embodiment, the ratio of the area S2, which is the area where the region of each of the first extending portion 223 and the second extending portion 233 that lies inward of the first gate mark 591 in the second direction y (the first region) overlaps with the first gate mark 591, to the area Si, which is the area of the first gate mark 591, is about 30%.

When a third dimension L3 represents the length in the second direction y of the region of each of the first extending portion 223 and the second extending portion 233 that lies inward of the first gate mark 591 in the second direction y (the first region), the ratio of the third dimension L3 to the second dimension L2 ranges from 50% to 100% (see FIG. 3). The ratio of the first distance D1 to the second dimension L2 is greater than 0% and less than or equal to 50% (see Figs. 3 and 9). In the illustrated example of the present embodiment, the third dimension L3 is about 2.5 mm.

In the present embodiment, a fourth dimension L4 represents the dimension between the resin obverse surface 51 and the resin reverse surface 52 in the thickness direction z, and the ratio of the first distance D1 to the fourth dimension L4 is greater than 0% and less than or equal to 70% (see FIGS. 3 and 9).

As shown in FIGS. 4 to 6, the second resin side surface 54 includes a second upper section 541, a second lower section 542, and a second intermediate section 543. The second upper section 541 is connected to the resin obverse surface 51 at the zl-side end in the thickness direction z and to the second intermediate section 543 at the z2-side end in the thickness direction z. The second upper section 541 is inclined relative to the resin obverse surface 51. The second lower section 542 is connected to the resin reverse surface 52 at the z2-side end in the thickness direction z and to the second intermediate section 543 at the zl-side end in the thickness direction z. The second lower section 542 is inclined relative to the resin reverse surface 52. The second intermediate section 543 is connected to the second upper section 541 at the zl-side end in the thickness direction z and to the second lower section 542 at the z2-side end in the thickness direction z. The in-plane direction of the second intermediate section 543 is parallel to both the thickness direction z and the second direction y. As viewed in the thickness direction z, the second intermediate section 543 lies outside the resin obverse surface 51 and the resin reverse surface 52.

As shown in FIG. 5, the second resin side surface 54 has a second gate mark 592. The surface of the second gate mark 592 is rougher than other regions of the second resin side surface 54. The second gate mark 592 is formed during the manufacturing process of the electronic device A1, which will be described later, resulting from cutting the sealing resin 5 at a second gate 892 in the step of forming the sealing resin 5. In the electronic device A1, the second gate mark 592 includes a region positioned in the second lower section 542 and a region positioned in the second intermediate section 543. The second gate mark 592 is positioned in the middle of the second resin side surface 54 in the second direction y.

As shown in FIGS. 3 to 5, the third resin side surface 55 includes a third upper section 551, a third lower section 552, and a third intermediate section 553. The third upper section 551 is connected to the resin obverse surface 51 at the zl-side end in the thickness direction z and to the third intermediate section 553 at the z2-side end in the thickness direction z. The third upper section 551 is inclined relative to the resin obverse surface 51. The third lower section 552 is connected to the resin reverse surface 52 at the z2-side end in the thickness direction z and to the third intermediate section 553 at the zl-side end in the thickness direction z. The third lower section 552 is inclined relative to the resin reverse surface 52. The third intermediate section 553 is connected to the third upper section 551 at the zl-side end in the thickness direction z and to the third lower section 552 at the z2-side end in the thickness direction z. The in-plane direction of the third intermediate section 553 is parallel to both the thickness direction z and the first direction x. As viewed in the thickness direction z, the third intermediate section 553 lies outside the resin obverse surface 51 and the resin reverse surface 52. A portion of each first lead terminal 22 protrudes from the third intermediate section 553.

As shown in FIGS. 3, 5, and 6, the fourth resin side surface 56 includes a fourth upper section 561, a fourth lower section 562, and a fourth intermediate section 563. The fourth upper section 561 is connected to the resin obverse surface 51 at the zl-side end in the thickness direction z and to the fourth intermediate section 563 at the z2-side end in the thickness direction z. The fourth upper section 561 is inclined relative to the resin obverse surface 51. The fourth lower section 562 is connected to the resin reverse surface 52 at the z2-side end in the thickness direction z and to the fourth intermediate section 563 at the zl-side end in the thickness direction z. The fourth lower section 562 is inclined relative to the resin reverse surface 52. The fourth intermediate section 563 is connected to the fourth upper section 561 at the zl-side end in the thickness direction z and to the fourth lower section 562 at the z2-side end in the thickness direction z. The in-plane direction of the fourth intermediate section 563 is parallel to both the thickness direction z and the first direction x. As viewed in the thickness direction z, the fourth intermediate section 563 lies outside the resin obverse surface 51 and the resin reverse surface 52.

A portion of each second lead terminal 23 protrudes from the fourth intermediate section 563.

Generally, a motor driver circuit of an inverter device forms a half-bridge circuit composed of a low-side switching element and a high-side switching element. The following description relates to an example in which the switching elements are MOSFETs. For the low-side switching element, the source of the switching element and the reference potential of the gate driver that drives the switching element are both grounded. For the high-side switching element, the source of the switching element and the reference potential of the gate driver that drives the switching element both correspond to the potential at the output node of the half-bridge circuit. The potential at the output node changes in response to the driving of the high-side and low-side switching elements, and thus the reference potential of the gate driver that drives the high-side switching element also changes. When the high-side switching element is on, the reference potential is equal to the voltage applied to the drain of the high-side switching element (e.g., 600 V or higher). In the electronic device A1, the ground of the first semiconductor element 11 and the ground of the second semiconductor element 13 are isolated from each other. Thus, when the electronic device Al is used as a gate driver for controlling the high-side switching element, the ground of the second semiconductor element 13 may be subjected to a transient voltage equal to the voltage applied to the drain of the high-side switching element.

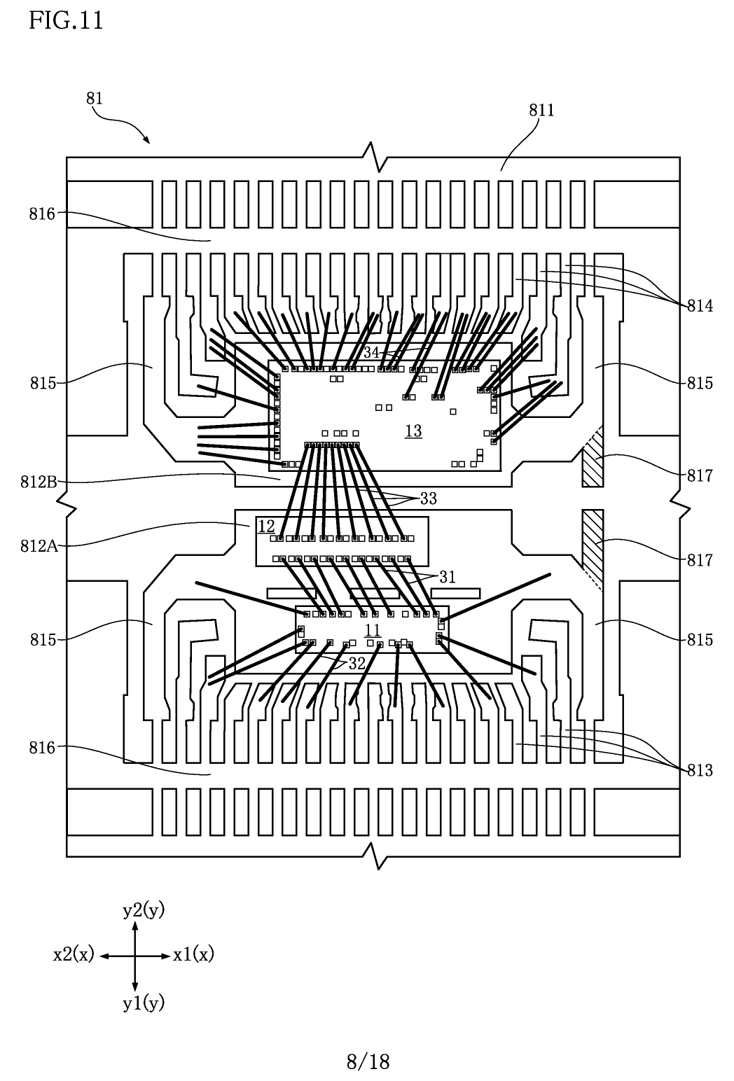

The following describes an example of a method for manufacturing a electronic device A1, with reference to FIGS. 10 to 12. FIGS. 10 to 12 are plan views each illustrating a step of the method for manufacturing an electronic device A1.

First, as shown in FIG. 10, a lead frame 81 is prepared. The lead frame 81 is a plate material. In the present embodiment, the base material of the lead frame 81 is copper. The lead frame 81 may be formed by applying etching or other processes to a metal plate, or by punching a metal plate. The lead frame 81 has an obverse surface 81A and a reverse surface 81B spaced apart from each other in the thickness direction z. The lead frame 81 is composed of an outer frame 811, a first die pad 812A, a second die pad 812B, a plurality of first leads 813, a plurality of second leads 814, a plurality of support leads 815, a plurality of dam bars 816, and a plurality of extending portions 817. The outer frame 811 and the dam bars 816 are not the portions forming the electronic device A1. The first die pad 812A is the portion that will later form the first die pad 21A. The second die pad 812B will later form the second die pad 21B. The first leads 813 will later form the plurality of first lead terminals 22. The second leads 814 will later form the plurality of second lead terminals 23. The support leads 815 will later form the first lead portion 221 of the first-side first terminal 22A, the second lead portion 231 of the first-side second terminal 23A, the lead portion 224 of the second-side first terminal 22B, and the lead portion 234 of the second-side second terminal 23B. The extending portions 817 will later form the first extending portion 223 of the first-side first terminal 22A and the second extending portion 233 of the first- side second terminal 23A.

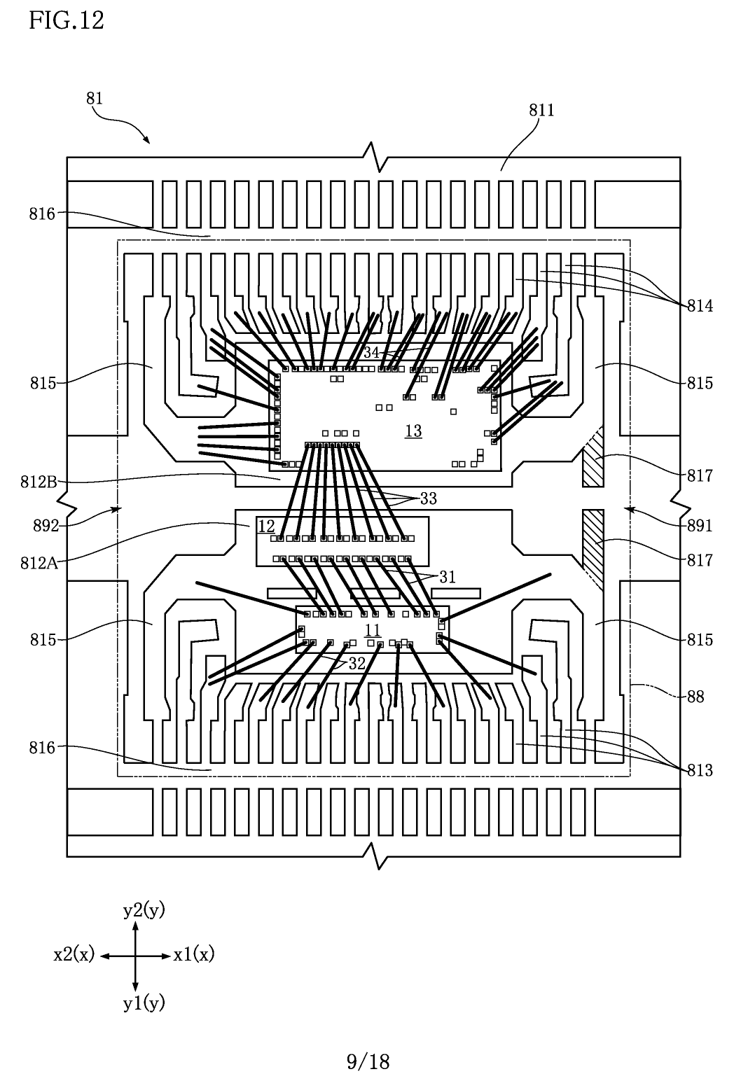

Subsequently, as shown in FIG. 11, the first semiconductor element 11 and the insulating element 12 are attached to the first die pad 812A by die bonding, and the second semiconductor element 13 is attached to the second die pad 812B also by die bonding. After these steps, a plurality of wires 31 to 34 are formed by wire bonding.

Subsequently, the sealing resin 5 is formed. The sealing resin 5 is formed by transfer molding. In this step, the lead frame 81 is placed into a mold having a plurality of cavities. Here, it is ensured that the portion of the lead frame 81 corresponding to the portion of the conductive support member 2 covered with the sealing resin 5 in the electronic device Al is accommodated in one of the cavities. Then, molten resin is injected from a pot through the runners to fill the cavities. As shown in FIG. 12, the lead frame 81 is formed with a first gate 891 and a second gate 892. The first gate 891 serves as an inlet through which molten resin enters the corresponding cavity 88. The second gate 892 serves as an outlet through which molten resin exits the corresponding cavity 88. The molten resin injected into the cavity 88 is solidified to form the sealing resin 5, after which resin burrs formed outside the cavity 88 are removed using high- pressure water, for example. Removing the resin burrs formed at the first gate 891 leaves the first gate mark 591 on the sealing resin 5. Similarly, removing the resin burrs formed at the second gate 892 leaves the second gate mark 592 on the sealing resin 5. This completes the formation of the sealing resin 5.

Subsequently, dicing is performed to isolate individual dies, separating the first die pad 812A, the second die pad 812B, the first leads 813, the second leads 814, and the support leads 815, which are connected by the outer frame 811 and dam bars 816. Through the steps described above, the electronic device Al is completed.

Next, the operation and effects of the electronic device Al will be described.

The electronic device Al includes the conductive support member 2, the plurality of electronic elements 1 on the zl side in the thickness direction z with respect to the conductive support member 2, and the sealing resin 5. The sealing resin 5 covers the electronic elements 1 and a portion of the conductive support member 2. The sealing resin 5 has the first resin side surface 53 facing the xl side in the first direction x. The first resin side surface 53 has a first gate mark 591 the surface of which is rougher than other regions of the first resin side surface 53. The first-side first terminal 22A (one of the plurality of first lead terminals 22 forming the conductive support member 2) includes the first extending portion 223, and the first-side second terminal 23A (one of the plurality of second lead terminals 23 forming the conductive support member 2) includes the second extending portion 233. The first extending portion 223 and the second extending portion 233 are the nearest portions of the conductive support member 2 to the first gate mark 591 in the first direction x. As viewed in the thickness direction z, the first extending portion 223 and the second extending portion 233 each include a region that lies inward of the first gate mark 591 in the second direction y (a first region). The ratio of the first distance D1, which represents the distance in the first direction x between the first gate mark 591 and the region of each of the first extending portion 223 and the second extending portion 233 that lies inward of the first gate mark 591 in the second direction y (the first region), and the first dimension L1, which represents the length of the first gate mark 591 in the thickness direction z, is greater than 0% and less than or equal to 500%.

This configuration ensures that the region of each of the first extending portion 223 and the second extending portion 233 that lies inward of the first gate mark 591 in the second direction y (the first region) is positioned relatively close to the first gate mark 591. During the step of forming the sealing resin 5, if the molten resin flows rapidly through the gate corresponding to the first gate mark 591, the resin may entrap air as it fills the cavity. In the present embodiment, the region of each of the first extending portion 223 and the second extending portion 233 that lies inward of the first gate mark 591 in the second direction y (the first region) is positioned relatively close to the first gate mark 591 as described above. Thus, the molten resin strikes the first regions of the first extending portion 223 and the second extending portion 233. This slows down the flow of the molten resin and thus reduces the risk of air entrapment. Consequently, pinholes (voids) due to air entrapment are reduced, thereby preventing incomplete filling in the sealing resin 5. Although the molten resin injected through the gate in the step of forming the sealing resin 5 may entrap air, the trapped air breaks down into finer bubbles as the molten resin strikes the first region (the region of each of the first extending portion 223 and the second extending portion 233 that lies inward of the first gate mark 591 in the second direction y), which is positioned relatively close to the first gate mark 591.

The first distance D1, which is the distance in the first direction x between the first gate mark 591 and the region of each of the first extending portion 223 and the second extending portion 233 that lies inward of the first gate mark 591 in the second direction y (the first region), is greater than 0 mm and less than or equal to 2.4 mm. This configuration ensures a significant decrease in the occurrence of pinholes in the step of forming the sealing resin 5.

The second dimension L2, which is the length of the first gate mark 591 in the second direction y, and the first distance D1 are related such that one becomes shorter as the other becomes longer. The product of the second dimension L2, which is the length of the first gate mark 591 in the second direction y, and the first distance D1 ranges from 0.21 mm2 to 5.0 mm2. In the step of forming the sealing resin 5, this configuration reduces the occurrence of pinholes while maintaining an appropriate resin filling rate (the amount of resin injected per unit time).

As viewed in the first direction x, the region of each of the first extending portion 223 and the second extending portion 233 that lies inward of the first gate mark 591 in the second direction y (the first region) overlaps with the first gate mark 591. As viewed in the first direction x, the ratio of the area S2, which is the area where the region of each of the first extending portion 223 and the second extending portion 233 that lies inward of the first gate mark 591 in the second direction y (the first region) overlaps with the first gate mark 591, to the area Si, which is the area of the first gate mark 591, is greater than 0% and less than or equal to 50%. This configuration ensures that the molten resin injected in the step of forming the sealing resin 5 reliably strikes the first regions of the first extending portion 223 and the second extending portion 233. This is favorable for preventing or reducing the occurrence of pinholes in the sealing resin 5 and can further reduce incomplete filling in the sealing resin 5.

The ratio of the third dimension L3, which is the length in the second direction y of the region of each of the first extending portion 223 and the second extending portion 233 that lies inward of the first gate mark 591 in the second direction y (the first region), to the second dimension L2, which is the length of the first gate mark 591 in the second direction y, ranges from 50% to 100%. The ratio of the first distance D1 to the second dimension L2 is greater than 0% and less than or equal to 50%. The ratio of the first distance D1 to the fourth dimension L4, which is the dimension between the resin obverse surface 51 and the resin reverse surface 52 in the thickness direction z, is greater than 0% and less than or equal to 70%. This configuration ensures a significant decrease in the occurrence of pinholes during the formation of the sealing resin 5, even though the second dimension L2, third dimension L3, and the fourth dimension L4, or other dimensions may vary depending on the size of the electronic device A1.

The plurality of electronic elements 1 include the first semiconductor element 11 (the first electronic element), the second semiconductor element 13 (the second electronic element), and the insulating element 12. The first semiconductor element 11, along with the first die pad 21A, forms a first circuit, while the second semiconductor element 13, along with the second die pad 21B, forms a second circuit. The insulating element 12 is mounted on either the first die pad 21A or the second die pad 21B and transmits signals between the first circuit and the second circuit while electrically isolating the first circuit and the second circuit. The electronic device Al of this configuration prevents or reduces the occurrence of pinholes within the sealing resin 5 as described above, thereby preventing a decrease in the dielectric strength of the discrete portions of the conductive support member 2.

### First Variation of First Embodiment:

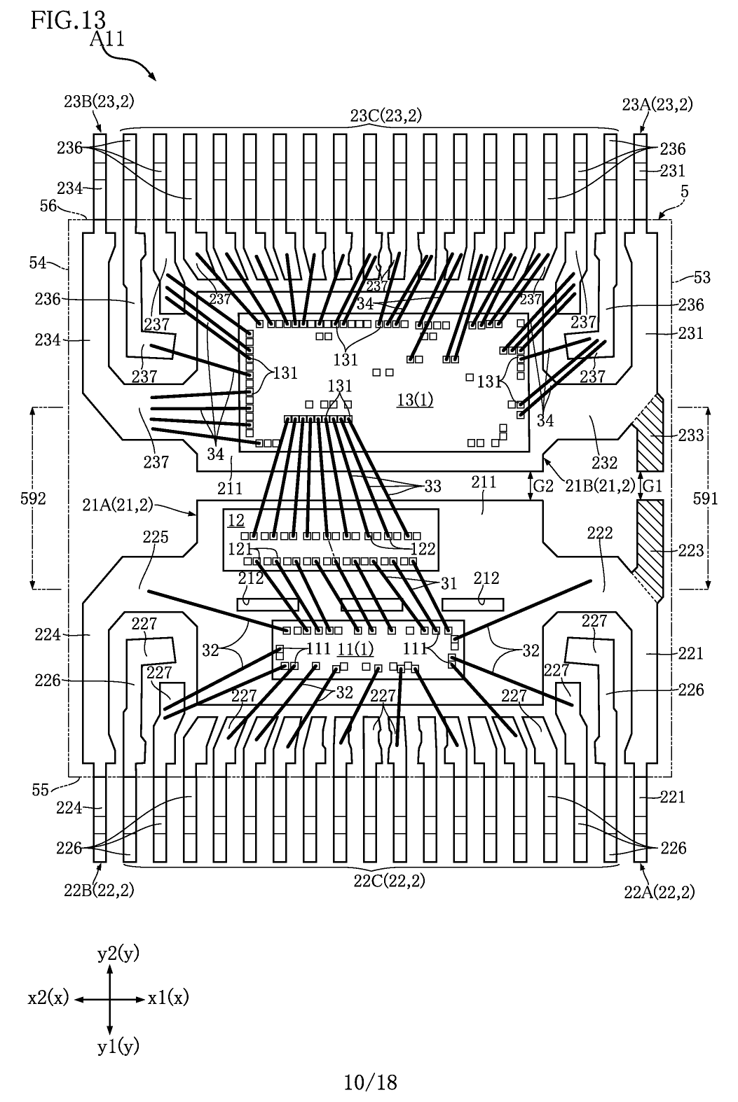

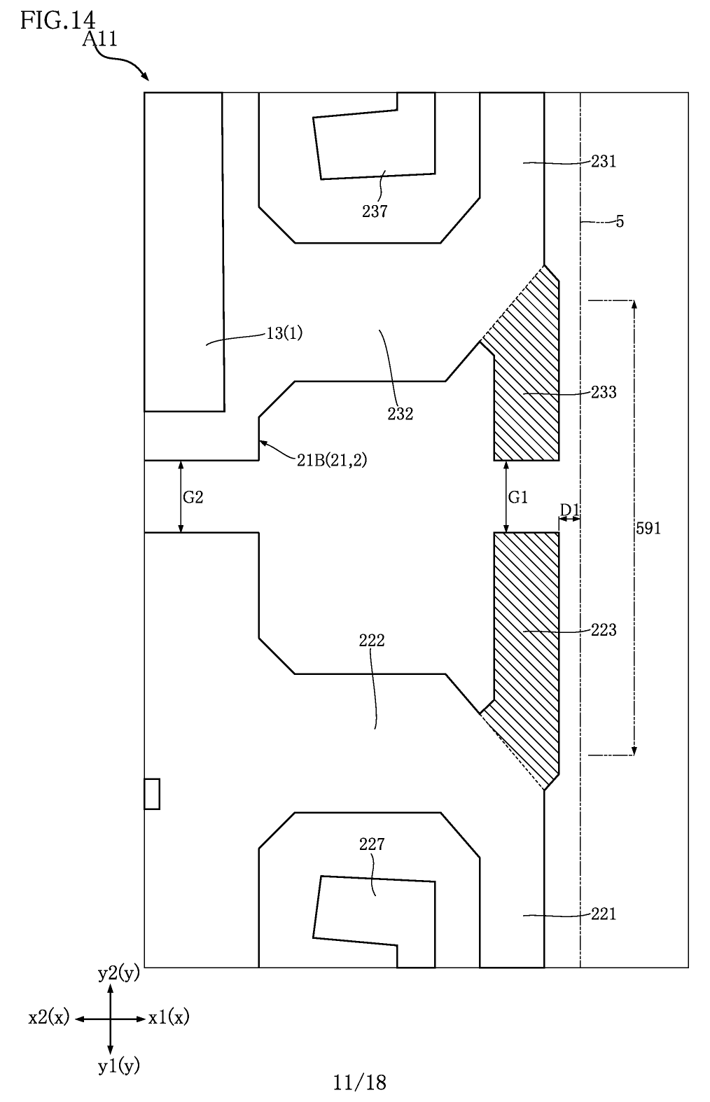

FIGS. 13 and 14 show an electronic device according to a first variation of the first embodiment. FIG. 13 is a plan view of the electronic device All according to this variation.

FIG. 14 is an enlarged view of a portion of FIG. 13. For ease of understanding, FIG. 13 depicts the sealing resin 5 as transparent. In FIG. 13, the outline of the sealing resin 5 is indicated by imaginary lines. In FIG. 13 and subsequent figures, elements that are identical or similar to those of the electronic device Al of the embodiment described above are denoted by the same reference numerals, and corresponding descriptions are omitted where appropriate.

The electronic device All of this variation differs from the electronic device Al of the embodiment described above in the configurations of the first-side first terminal 22A and the first- side second terminal 23A. In the first-side first terminal 22A, the first extending portion 223 is positioned farther outward than the first lead portion 221 on the xl side in the first direction x. In the first-side second terminal 23A, the second extending portion 233 is positioned farther outward than the second lead portion 231 on the x1 side in the first direction x. The first extending portion 223 and the second extending portion 233 are both positioned farther outward on the xl side in the first direction x, compared with the corresponding portions of the electronic device Al of the embodiment described above. Hence, for the region of each of the first extending portion 223 and the second extending portion 233 that lies inward of the first gate mark 591 in the second direction y (the first region), the first distance D1 between the first gate mark 591 and the first region in the first direction x is shorter than the first distance D1 in the electronic device A1.

In the electronic device All of this variation, the region of each of the first extending portion 223 and the second extending portion 233 that lies inward of the first gate mark 591 in the second direction y (the first region) is positioned relatively close to the first gate mark 591.

During the step of forming the sealing resin 5, if the molten resin flows rapidly through the gate corresponding to the first gate mark 591, the resin may entrap air as it fills the cavity. In the present variation, the region of each of the first extending portion 223 and the second extending portion 233 that lies inward of the first gate mark 591 in the second direction y (the first region) is positioned relatively close to the first gate mark 591 as described above. Thus, the molten resin strikes the first regions of the first extending portion 223 and the second extending portion 233.

This slows down the flow of the molten resin and thus reduces the risk of air entrapment. Consequently, pinholes (voids) due to air entrapment are reduced, thereby preventing incomplete filling in the sealing resin 5. Although the molten resin injected through the gate in the step of forming the sealing resin 5 may entrap air, the trapped air breaks down into finer bubbles as the molten resin strikes the first region (the region of each of the first extending portion 223 and the second extending portion 233 that lies inward of the first gate mark 591 in the second direction y), which is positioned relatively close to the first gate mark 591.

In the electronic device All of this variation, the first-side first terminal 22A has the first extending portion 223 that is positioned farther outward than the first lead portion 221 on the xl side in the first direction x. The first-side second terminal 23A has the second extending portion 233 that is positioned farther outward than the second lead portion 231 on the xl side in the first direction x. This shortens the first distance D1 in the first direction x between the first gate mark 591 and the region of each of the first extending portion 223 and the second extending portion 233 that lies inward of the first gate mark 591 in the second direction y (the first region). This configuration is favorable for preventing or reducing the occurrence of pinholes in the sealing resin 5 and can further reduce incomplete filling in the sealing resin 5. Additionally, the electronic device All achieves the same operation and effects as the electronic device Al of the above- described embodiment.

### Second Embodiment:

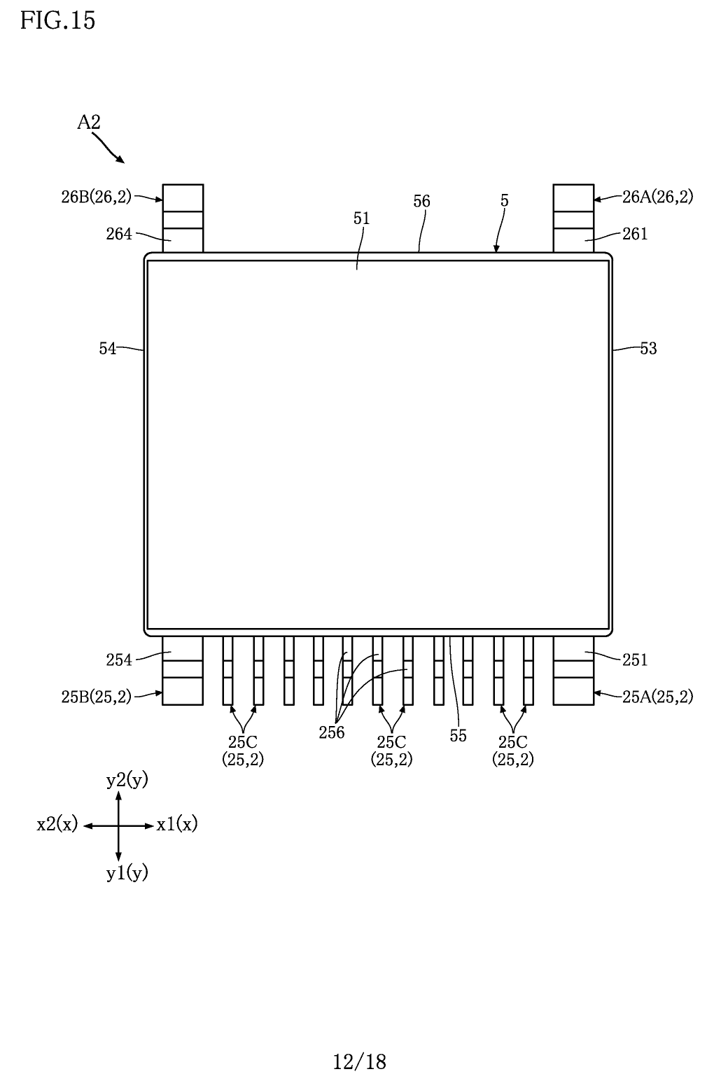

With reference to FIGS. 15 to 23 the following describes an electronic device according to a second embodiment of the present disclosure. The electronic device A2 of the present embodiment includes a plurality of electronic elements 1, a conductive support member 2, a plurality of wires 41 to 46, and a sealing resin 5. Although the specific usage or other details of the electronic device A2 are not particularly limited, it may be used, for example, to detect the battery voltage of an electric vehicle. Alternatively, the electronic device A2 may be used to detect a voltage other than battery voltage of the electric vehicle, or may be used to detect a voltage in other devices, including industrial device, home appliances, or a power supply devices. The electronic device A2 is a semiconductor package for surface mounting, specifically an SOP (Small Outline Package) in this embodiment as shown in FIGS. 15 to 23.

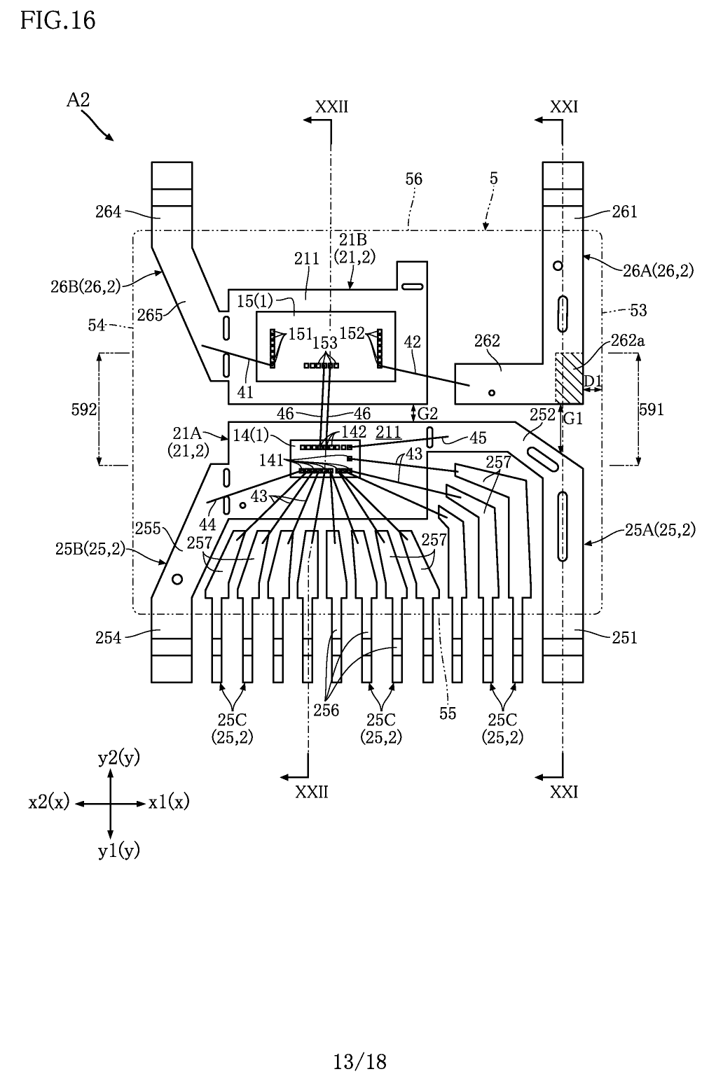

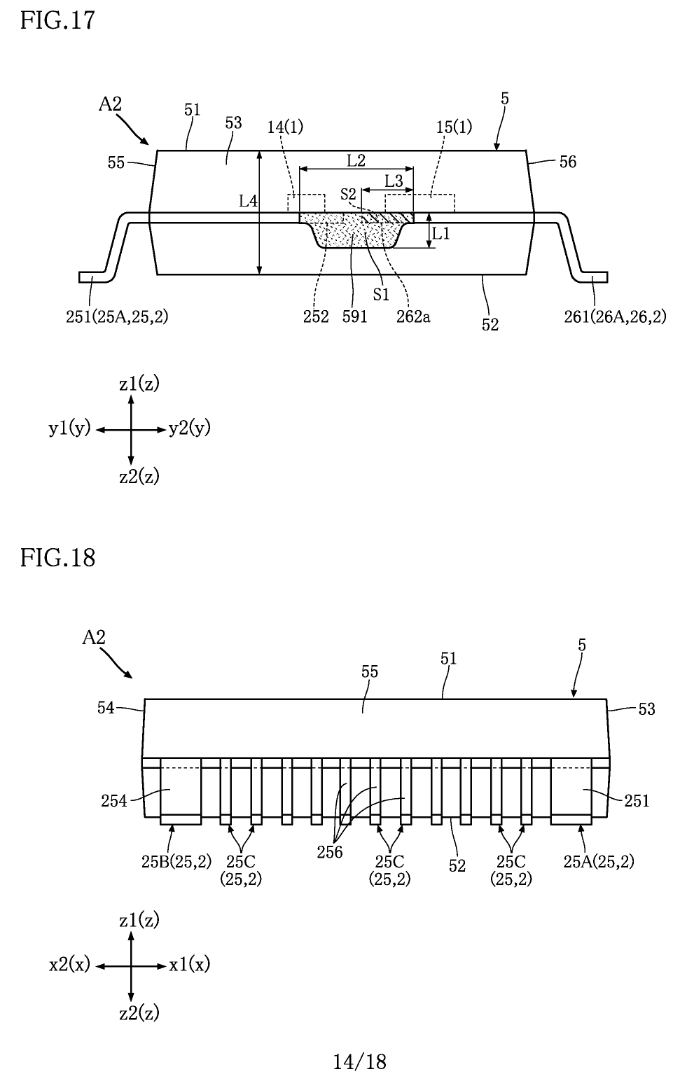

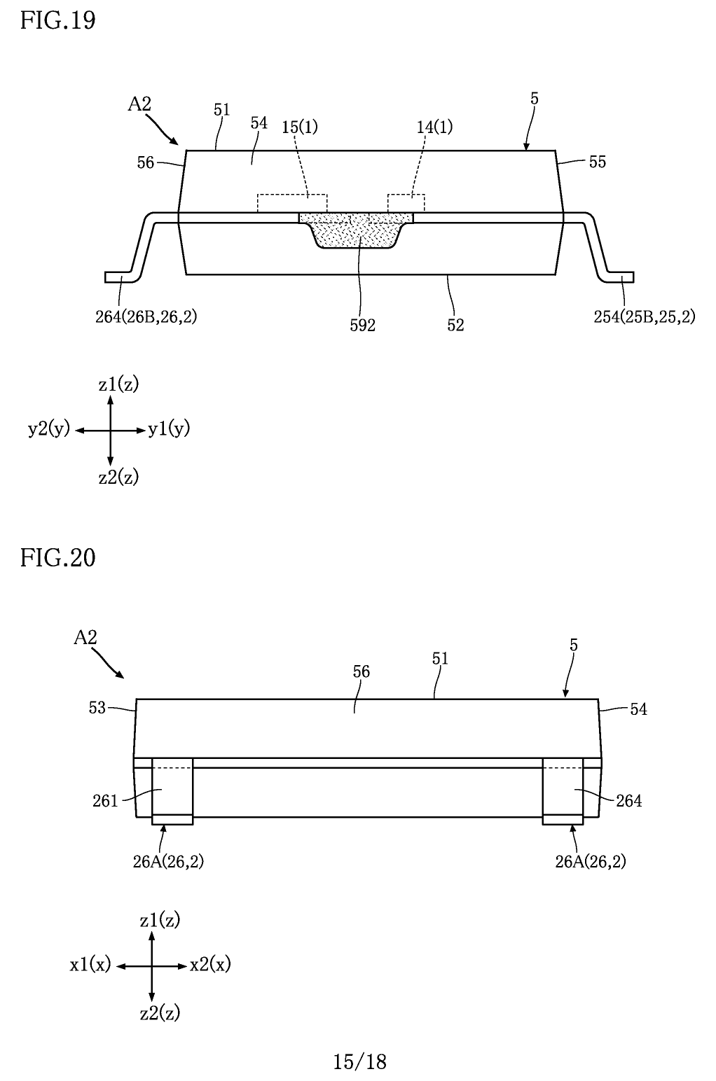

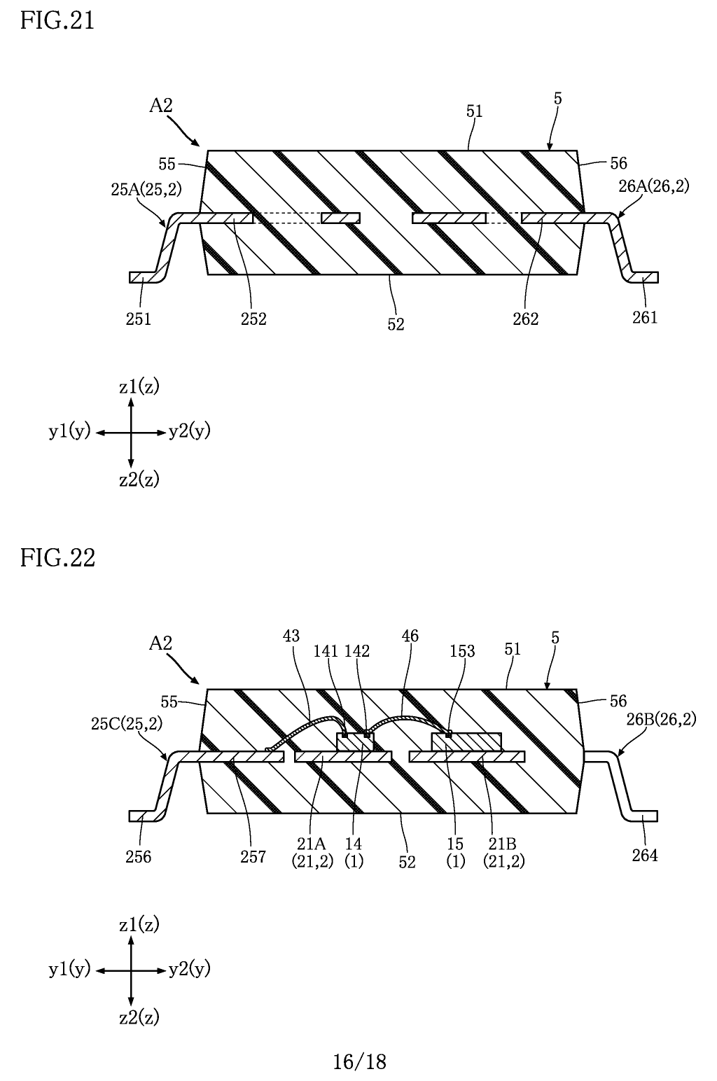

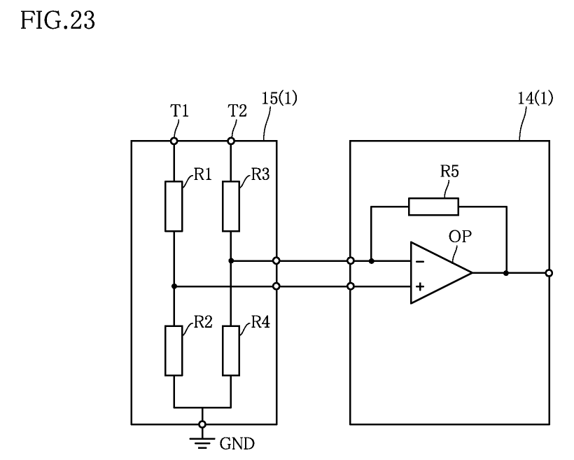

FIGS. 15 and 16 are plan views of the electronic device A2 according to the present embodiment. FIG. 17 is a front view of the electronic device A2. FIG. 18 is a left-side view of the electronic device A2. FIG. 19 is a rear view of the electronic device A2. FIG. 20 is a right- side view of the electronic device A2. FIG. 21 is a sectional view taken along line XXI-XXI in FIG. 16. FIG. 22 is a sectional view taken along line XXII-XXII in FIG. 16. FIG. 23 is a circuit diagram of the electronic device A2. For ease of understanding, FIG. 16 depicts the sealing resin 5 as transparent. In FIG. 16, the outline of the sealing resin 5 is indicated by imaginary lines.

Also, in the description of electronic device A2, reference is made to the three mutually perpendicular directions: the thickness direction z, the first direction x, and the second direction y as needed. As shown in FIGS. 15 and 16, the electronic device A2 is rectangular (or substantially rectangular) as viewed in the thickness direction z (in plan view).

The conductive support member 2 of the electronic device A2 is a component that forms a conduction path between the plurality of electronic elements 1 and the circuit board of an electric vehicle, for example. The conductive support member 2 contains metals, such as copper, nickel, or iron (Fe). As shown in FIGS. 15 and 16, the conductive support member 2 includes a die pad portion 21, a plurality of first lead terminals 25, and a plurality of second lead terminals 26. The conductive support member 2 is obtained from one lead frame. The conductive support member 2 is made by applying one or more selected processes, including punching, bending, and etching. The conductive support member 2 (the die pad portion 21, the first lead terminals 25, and the second lead terminals 26) may have plating layers of silver, nickel, or gold, covering certain portions as needed.

The die pad portion 21 supports the electronic elements 1. In the present embodiment, the die pad portion 21 includes a first die pad 21A and a second die pad 21B. The first die pad 21A is positioned on the yl side in the second direction y, whereas the second die pad 21B is positioned on the y2 side in the second direction y. The first die pad 21A and the second die pad 21B are spaced apart from each other in the second direction y. The die pad portion 21 (each of the first die pad 21A and the second die pad 21B) has a mounting surface 211 facing the zl side in the thickness direction z. In the illustrated example, the first die pad 21A and the second die pad 21B are rectangular in plan view, although the shape is not limited to this.

The first lead terminals 25 are bonded to the wiring board of, for example, an electric vehicle, to provide a conduction path between the electronic device A2 and the wiring board. As shown in FIGS. 15, 16, and 18, the first lead terminals 25 are arranged along the first direction x with spacing between them. The first lead terminals 25 protrude from the sealing resin 5 (the third resin side surface 55, which will be described later) toward the yl side in the second direction y and thus are exposed. The plurality of first lead terminals 25 include a first-side first terminal 25A, a second-side first terminal 25B, and a plurality of intermediate first terminals 26C.

The first-side first terminal 25A is the outermost one on the xl side in the first direction x, among the plurality of first lead terminals 25. As shown in FIG. 16, the first-side first terminal 25A includes a terminal portion 251 and a lead portion 252.

The terminal portion 251 of the first-side first terminal 25A is exposed from the sealing resin 5. The terminal portion 251 protrudes from the sealing resin 5 toward the yl side in the second direction y. In plan view, the terminal portion 251 has a rectangular shape elongated in the second direction y. As shown in FIG. 17, the terminal portion 251 is bent into a gull-wing shape as viewed in the first direction x. When the electronic device A2 is attached to a circuit board of, for example, an electric vehicle, the end of the terminal portion 251 is bonded to the circuit board.

The lead portion 252 of the first-side first terminal 25A is covered with the sealing resin 5. The lead portion 252 is connected to the terminal portion 251 and extends inward from the terminal portion 251 into the sealing resin 5. In plan view, the lead portion 252 has bends as needed, forming a portion that extends in the second direction y, a portion that extends in the first direction x, and a portion that connects the two portions, extending in a direction inclined to both the second direction y and the first direction x. The lead portion 252 is connected to the first die pad 21A at the end opposite the terminal portion 251.

The second-side first terminal 25B is the outermost one on the x2 side in the first direction x among the plurality of first lead terminals 25. As shown in FIG. 16, the second-side first terminal 25B includes a terminal portion 254 and a lead portion 255.

The terminal portion 254 of the second-side first terminal 25B is exposed from the sealing resin 5. The terminal portion 254 protrudes from the sealing resin 5 toward the yl side in the second direction y. In plan view, the terminal portion 254 has a rectangular shape elongated in the second direction y. As shown in FIG. 19, the terminal portion 254 is bent into a gull-wing shape as viewed in the first direction x. When the electronic device A2 is attached to a circuit board of, for example, an electric vehicle, the end of the terminal portion 254 is bonded to the circuit board.

The lead portion 255 of the second-side first terminal 25B is covered with the sealing resin 5. The lead portion 255 is connected to the terminal portion 254 and extends inward from the terminal portion 254 into the sealing resin 5. The lead portion 255 is connected to the first die pad 21A at the end opposite the terminal portion 254.

As shown in FIGS. 16 and 18, the intermediate first terminals 25C are positioned between the first-side first terminal 25A and the second-side first terminal 25B. As shown in FIG. 16, each intermediate first terminal 25C includes a terminal portion 256 and a lead portion 257. That is, the electronic device A2 includes a plurality of terminal portions 256 and a plurality of lead portions 257. The following describes the terminal portion 256 and the lead portion 257 of an intermediate first terminal 25C, and unless otherwise specifically noted, the description commonly applies to all intermediate first terminals 25C.

The terminal portion 256 of the intermediate first terminal 25C is exposed from the sealing resin 5. The terminal portion 254 protrudes from the sealing resin 5 toward the yl side in the second direction y. In plan view, the terminal portion 256 has a rectangular shape elongated in the second direction y. The plurality of terminal portions 256 are arranged at equal intervals along the first direction x. As shown in FIG. 21 and other figures, the terminal portion 256 is bent into a gull-wing shape as viewed in the first direction x. As viewed in the first direction x, the terminal portions 256 overlap with each other. When the electronic device A2 is attached to a circuit board of, for example, an electric vehicle, the end of the terminal portion 256 is bonded to the circuit board.

The lead portion 257 of the intermediate first terminal 25C is covered with the sealing resin 5. The lead portion 257 is connected to the terminal portion 256 and extends inward from the terminal portion 256 into the sealing resin 5.

The second lead terminals 26 are bonded to the wiring board of, for example, an electric vehicle, to provide a conduction path between the electronic device A2 and the wiring board. As shown in FIGS. 15, 16, and 20, the second lead terminals 26 are arranged along the first direction x with spacing between them. The second lead terminals 26 protrude from the sealing resin 5 (the fourth resin side surface 56, which will be described later) toward the y2 side in the second direction y and thus are exposed. The plurality of second lead terminals 26 include a first-side second terminal 26A and a second-side second terminal 26B.

The first-side second terminal 26A is the outermost one on the xl side in the first direction x, among the plurality of second lead terminals 26. As shown in FIG. 16, the first-side second terminal 26A includes a terminal portion 261 and a lead portion 262.

The terminal portion 261 of the first-side second terminal 26A is exposed from the sealing resin 5. The terminal portion 261 protrudes from the sealing resin 5 toward the y2 side in the second direction y. In plan view, the terminal portion 261 has a rectangular shape elongated in the second direction y. As shown in FIG. 17, the terminal portion 261 is bent into a gull-wing shape as viewed in the first direction x. When the electronic device A2 is attached to a circuit board of, for example, an electric vehicle, the end of the terminal portion 261 is bonded to the circuit board.

The lead portion 262 of the first-side second terminal 26A is covered with the sealing resin 5. The lead portion 262 is connected to the terminal portion 261 and extends inward from the terminal portion 261 into the sealing resin 5. In plan view, the lead portion 262 has a bend as needed, forming a portion that extends in the second direction y, and a portion that extends in the first direction x.

The second-side second terminal 26B is the outermost one on the x2 side in the first direction x, among the plurality of second lead terminals 26. As shown in FIG. 16, the second- side second terminal 26B includes a terminal portion 264 and a lead portion 265.

The terminal portion 264 of the second-side second terminal 26B is exposed from the sealing resin 5. The terminal portion 264 protrudes from the sealing resin 5 toward the y2 side in the second direction y. In plan view, the terminal portion 264 has a rectangular shape elongated in the second direction y. As shown in FIG. 19, the terminal portion 264 is bent into a gull-wing shape as viewed in the first direction x. When the electronic device A2 is attached to a circuit board of, for example, an electric vehicle, the end of the terminal portion 264 is bonded to the circuit board.

The lead portion 265 of the second-side second terminal 26B is covered with the sealing resin 5. The lead portion 265 is connected to the terminal portion 264 and extends inward from the terminal portion 264 into the sealing resin 5. The lead portion 265 is connected to the second die pad 21B at the end opposite the terminal portion 264.

For the electronic device A2, the geometries and relative positions of the conductive support member 2 (the first die pad 21A, the second die pad 21B, the first lead terminals 25, and the second lead terminals 26) are not limited to those in the illustrated example and can be changed as needed depending on the specifications of the electronic device A2.

The electronic elements 1 are components that perform the electrical functions of the electronic device A2. Although the function of the electronic elements 1 are not particularly limited, the electronic elements 1 in this embodiment detect a voltage. In the illustrated example, the plurality of electronic elements 1 include a first electronic element 14 and a second electronic element 15, both of which are discrete elements.

The second electronic element 15 is mounted on the mounting surface 211 of the second die pad 21B. In the present embodiment, the second electronic element 15 outputs a first signal corresponding to the potential of the second-side second terminal 26B and a second signal corresponding to the potential of the first-side second terminal 26A, both to the first electronic element 14. The second electronic element 15 is provided with a plurality of electrodes 151, 152, and 153 on its upper surface in the thickness direction z.

The first electronic element 14 is mounted on the first die pad 21A. In the present embodiment, the first electronic element 14 receives the first signal and the second signal from the second electronic element 15, and outputs a third signal corresponding to the potential difference between the second-side second terminal 26B and the first-side second terminal 26A. In short, the first electronic element 14 outputs a detection signal (the third signal) that represents the voltage applied between the second-side second terminal 26B and the first-side second terminal 26A. The first electronic element 14 is provided with a plurality of electrodes 141 and 142 on its upper surface in the thickness direction z.

In the electronic device A2, the electronic elements 1 (the first electronic element 14 and the second electronic element 15) are arranged in the circuit configuration shown in FIG. 23, for example. As shown in FIG. 23, the second electronic element 15 includes a plurality of resistive elements R1 to R4, whereas the first electronic element 14 includes an operational amplifier OP and a resistive element R5. The circuit configuration of the electronic elements 1 is not limited to the example shown in FIG. 23.

The two resistive elements R1 and R2 are connected in series. The two resistive elements R1 and R2 divide the voltage at the terminal T1 (the potential difference between the potential of the terminal T1 and the reference potential of ground GND). In the present embodiment, the terminal T1 corresponds to the electrodes 152. The connection point of the two resistive elements R1 and R2 is connected to the non-inverting input terminal of the operational amplifier OP. The two resistive elements R3 and R4 are connected in series. The two resistive elements R3 and R4 divide the voltage at the terminal T2 (the potential difference between the potential of the terminal T2 and the reference potential of ground GND). In the present embodiment, the terminal T2 corresponds to the electrodes 151. The connection point of the two resistive elements R3 and R4 is connected to the inverting input terminal of the operational amplifier OP. For the electronic device A2 to detect the voltage of the battery mounted on an electric vehicle, one of the terminals T1 and T2 is electrically connected to the high-side terminal of the battery, and the other to the low-side terminal of the battery.

The operational amplifier OP receives the first signal corresponding to the potential of the terminal T1 (in the present embodiment, the signal obtained by dividing the voltage at the terminal T1) and the second signal corresponding to the potential of the terminal T2 (in the present embodiment, the signal obtained by dividing the voltage at the terminal T2), and outputs a third signal corresponding to the potential difference between the terminals T1 and T2. The resistive element R5 is a component that determines the amplification gain of the operational amplifier OP (a feedback resistor). The resistive element R5 has one end connected to the inverting input terminal of the operational amplifier OP and the other end to the output terminal of the operational amplifier OP. Note that the first electronic element 14 may not include the resistive element R5.

The wires 41 to 46 electrically connect portions that are spaced apart from each other.

The wires 41 to 46 are bonding wires. The wires 41 to 46 each contain either gold, aluminum, or copper.

As shown in FIG. 16, the wire 41 is bonded to the electrode 151 of the second electronic element 15 and to the lead portion 265, electrically connecting the second electronic element 15 and the second-side second terminal 26B. That is, the terminal portion 264 of the second-side second terminal 26B is electrically connected to the second electronic element 15 via the wire 41.

As shown in FIG. 16, the wire 42 is bonded to the electrode 152 of the second electronic element 15 and to the lead portion 262, electrically connecting the second electronic element 15 and the first-side second terminal 26A. That is, the terminal portion 261 of the first-side second terminal 26A is electrically connected to the second electronic element 15 via the wire 42.

As shown in FIG. 16, each wire 43 is bonded to an electrode 141 of the first electronic element 14 and to a lead portion 257, electrically connecting the first electronic element 14 and the corresponding intermediate first terminal 25C. In short, the terminal portion 256 of each intermediate first terminal 25C is electrically connected to the first electronic element 14 via the corresponding wire 43.

As shown in FIG. 16, the wire 44 is bonded to an electrode 141 of the first electronic element 14 and the lead portion 255, electrically connecting the first electronic element 14 and the second- side first terminal 25B. That is, the terminal portion 254 of the second-side first terminal 25B is electrically connected to the first electronic element 14 via the wire 44.

As shown in FIG. 16, the wire 45 is bonded to an electrode 141 of the first electronic element 14 and to the lead portion 252, electrically connecting the first electronic element 14 and the first- side first terminal 25A. That is, the terminal portion 251 of the first-side first terminal 25A is electrically connected to the first electronic element 14 via the wire 45.

As shown in FIG. 16, each wire 46 is bonded to an electrode 153 of the second electronic element 15 and to an electrode 142 of the first electronic element 14, electrically connecting the second electronic element 15 and the first electronic element 14. Thus, the wires 46 also serve as the transmission paths for the first and second signals.

The sealing resin 5 covers the die pad portion 21 (the first die pad 21A and the second die pad 21B), a portion of each first lead terminal 25, a portion of each second lead terminal 26, the

electronic elements 1 (the first electronic element 14 and the second electronic element 15), and the wires 41 to 46. The sealing resin 5 includes an insulating material, such as epoxy resin.

Preferably, the sealing resin 5 is made of a resin material with a CTI (comparative tracking index) of 600 V or higher. The sealing resin 5 is in the shape of a rectangular parallelepiped, for example. The sealing resin 5 has a dimension ranging from 5 mm to 15 mm in the first direction x, and from

3 mm to 13 mm in the second direction y.

As shown in FIGS. 17 to 20, the sealing resin 5 has a resin obverse surface 51, a resin reverse

surface 52, a first resin side surface 53, a second resin side surface 54, a third resin side surface

55, and a fourth resin side surface 56.

As shown in FIGS. 17 to 20, the resin obverse surface 51 and the resin reverse surface 52

are spaced apart from each other in the thickness direction z. The resin obverse surface 51 and the resin reverse surface 52 face away from each other in the thickness direction z. The resin obverse surface 51 faces the zl side in the thickness direction z, whereas the resin reverse surface 52 faces the z2 in the thickness direction z. The resin obverse surface 51 and the resin reverse surface 52 are both flat (or substantially flat).

As shown in FIGS. 17 to 20, the first resin side surface 53, the second resin side surface 54, the third resin side surface 55, and the fourth resin side surface 56 each connected to the resin obverse surface 51 and the resin reverse surface 52 and positioned between the resin obverse surface 51 and the resin reverse surface 52 in the thickness direction z. As shown in FIGS. 15, 18, and 20, the first resin side surface 53 is positioned on the xl side in the first direction x and faces the xl side in the first direction x. The second resin side surface 54 is positioned on the x2 side in the first direction x and faces the x2 side in the first direction x. The third resin side surface 55 and the fourth resin side surface 56 are spaced apart from each other in the second direction y and connected to the first resin side surface 53 and the second resin side surface 54. As shown in FIGS. 15, 17, and 19, the third resin side surface 55 is positioned on the yl side in the second direction y and faces the yl side in the second direction y. A portion of each first lead terminal 25 protrudes from the third resin side surface 55. The fourth resin side surface 56 is positioned on the y2 side in the second direction y and faces the y2 side in the second direction y. A portion of each second lead terminal 26 protrudes from the fourth resin side surface 56.

As shown in FIG. 17, the first resin side surface 53 has a first gate mark 591. The surface of the first gate mark 591 is rougher than other regions of the first resin side surface 53. Similarly to the manufacturing process of the electronic device Al described above (see FIG. 12), the first gate mark 591 results from cutting the sealing resin 5 at a first gate 891 in the step of forming the sealing resin 5. The first gate mark 591 is slightly offset from the center of the first resin side surface 53 in the second direction y toward the y2 side in the second direction y.

As shown in FIG. 16, the lead portion 262 of the first-side second terminal 26A includes an inner region 262a that lies inward of the first gate mark 591 in the second direction y, as viewed in the thickness direction z. The inner region 262a is the nearest region of the conductive support member 2 to the first gate mark 591 in the first direction x. The inner region 262a is an example of the "first region" recited in the present disclosure. FIGS. 16 and 17 show the inner region 262a with hatching.

In the present embodiment, as shown in FIG. 17, the inner region 262a (the first region) overlaps with the first gate mark 591 as viewed in the first direction x. In the illustrated example, the entirety of the inner region 262a overlaps with the first gate mark 591 as viewed in the first direction x.

inner region 262a (the first region). In the present embodiment, a first distance D1 represents the distance in the first direction x between the first gate mark 591 and inner region 262a, and a first dimension L1 represents the length of the first gate mark 591 in the thickness direction z (see FIGS. 16 and 17). The ratio of the first distance D1 to the first dimension L1 is in the range greater than 0% and less than or equal to 500%, and preferably within the range of 40% to 200%. The specific value of the first distance D1 is, for example, greater than 0 mm and less than or equal to 2.4 mm, and more preferably ranges from 0.21 mm to 1.0 mm. In the illustrated example of the present embodiment, the first distance D1 is about 0.35 mm. In the illustrated example, the first dimension Li is about 0.5 mm.

In the present embodiment, the following holds between the first gate mark 591 and the When a second dimension L2 represents the length of the first gate mark 591 in the second direction y, the second dimension L2 and the first distance D1 are related such that one becomes shorter as the other becomes longer (see FIG. 17). The second dimension L2 ranges from 1.0 mm to 5.0 mm, for example, and the product of the second dimension L2 and the first distance D1 ranges from 0.21 mm2 to 5.0 mm2, for example. In the illustrated example of the present embodiment, the second dimension L2 is about 3.0 mm.

As viewed in the first direction x, an area S1 represents the area of the first gate mark 591, area S2, which is the area where the inner region 262a overlaps with the first gate mark 591, to the area Si, which is the area of the first gate mark 591, is about 15%. and an area S2 represents the area where the inner region 262a (the first region) overlaps with the first gate mark 591. The ratio of the area S2 to the area S1 is greater than 0% and less than or equal to 50% (see FIG. 17). In the illustrated example of the present embodiment, the ratio of L2 is greater than 0% and less than or equal to 50% (see FIGS. 16 and 17). In the illustrated when a third dimension L3 represents of the length of the inner region 262a (the first region) in the second direction y, the ratio of the third dimension L3 to the second dimension L2 ranges from 50% to 100% (see FIG. 17). The ratio of the first distance D1 to the second dimension example of the present embodiment, the third dimension L3 is about 1.5 mm.

In the present embodiment, a fourth dimension L4 is the dimension between the resin obverse surface 51 and the resin reverse surface 52 in the thickness direction z, and the ratio of the first distance D1 to the fourth dimension L4 is greater than 0% and less than or equal to 70% (see FIGS. 16 and 17).

As shown in FIG. 19, the second resin side surface 54 has a second gate mark 592. The surface of the second gate mark 592 is rougher than other regions of the second resin side surface 54. Similarly to the manufacturing process of the electronic device Al described above (see FIG. 12), the second gate mark 592 results from cutting the sealing resin 5 at a second gate 892 in the step of forming the sealing resin 5. The second gate mark 592 is slightly offset from the center of the second resin side surface 54 in the second direction y toward the y2 side in the second direction y.

Next, the operation and effects of the electronic device A2 will be described. The electronic device A2 includes the conductive support member 2, the plurality of electronic elements 1 on the zl side in the thickness direction z with respect to the conductive support member 2, and the sealing resin 5. The sealing resin 5 covers the electronic elements 1 and a portion of the conductive support member 2. The sealing resin 5 has the first resin side surface 53 facing the xl side in the first direction x. The first resin side surface 53 has a first gate mark 591 the surface of which is rougher than other regions of the first resin side surface 53. The first-side second terminal 26A (one of the second lead terminals 26 forming the conductive support member 2) includes the lead portion 262. The lead portion 262 includes the inner region 262a that lies inward of the first gate mark 591 in the second direction y, as viewed in the thickness direction z (the first region). The inner region 262a is the nearest region of the conductive support member 2 to the first gate mark 591 in the first direction x. The ratio of the first distance D1, which represents the distance between the first gate mark 591 and the inner region 262a (the first region) in the first direction x, and the first dimension L1, which represents the length of the first gate mark 591 in the thickness direction z, is greater than 0% and less than or equal to 500%.

This configuration ensures that the inner region 262a of the lead portion 262 that lies inward of the first gate mark 591 in the second direction y (the first region) is positioned relatively close to the first gate mark 591. During the step of forming the sealing resin 5, if the molten resin flows rapidly through the gate corresponding to the first gate mark 591, the resin may entrap air as it fills the cavity. In the present embodiment, the inner region 262a that lies inward of the first gate mark 591 in the second direction y (the first region) is positioned relatively close to the first gate mark 591 as described above. Thus, the molten resin strikes the inner region 262a (the first region), thereby slowing its flow and thus reducing the risk of air entrapment. Consequently, pinholes (voids) due to air entrapment are reduced, thereby preventing incomplete filling in the sealing resin 5. Although the molten resin injected through the gate in the step of forming the sealing resin 5 may entrap air, the trapped air breaks down into finer bubbles as the molten resin strike the first region (the inner region 262a of the lead portion 262 that lies inward of the first gate mark 591 in the second direction y), which is positioned relatively close to the first gate mark 591.

The first distance D1, which is the distance between the first gate mark 591 and the inner region 262a (the first region) in the first direction x, is greater than 0 mm and less than or equal to 2.4 mm. This configuration ensures a significant decrease in the occurrence of pinholes during the formation of the sealing resin 5.

The length of the first gate mark 591 in the second direction y (the second dimension L2) and the first distance D1 are related such that one becomes shorter as the other becomes longer.

The product of the second dimension L2, which is the length of the first gate mark 591 in the second direction y, and the first distance D1 ranges from 0.21 mm2 to 5.0 mm2. In the step of forming the sealing resin 5, this configuration reduces the occurrence of pinholes while maintaining an appropriate resin filling rate (the amount of resin injected per unit time).

As viewed in the first direction x, the inner region 262a (the first region) overlaps with the first gate mark 591. As viewed in the first direction x, the ratio of the area S2, which is the area where the inner region 262a (the first region) overlaps with the first gate mark 591, to the area S i, which is the area of the first gate mark 591, is greater than 0% and less than or equal to 50%.

This configuration ensures that the molten resin injected in the step of forming the sealing resin 5 reliably strikes the inner region 262a (the first region). This is favorable for preventing or reducing the occurrence of pinholes in the sealing resin 5 and can further reduce incomplete filling in the sealing resin 5.

The ratio of the third dimension L3, which is the length of the inner region 262a (the first region) in the second direction y, to the second dimension L2, which is the length of the first gate mark 591 in the second direction y, ranges from 50% to 100%. The ratio of the first distance D1 to the second dimension L2 is greater than 0% and less than or equal to 50%. The ratio of the first distance D1 to the fourth dimension L4, which is the dimension between the resin obverse surface 51 and the resin reverse surface 52 in the thickness direction z, is greater than 0% and less than or equal to 70%. This configuration ensures a significant decrease in the occurrence of pinholes during the formation of the sealing resin 5, even though the second dimension L2, third dimension L3, and the fourth dimension L4, or other dimensions may vary depending on the size of the electronic device A2.

### First Variation of Second Embodiment:

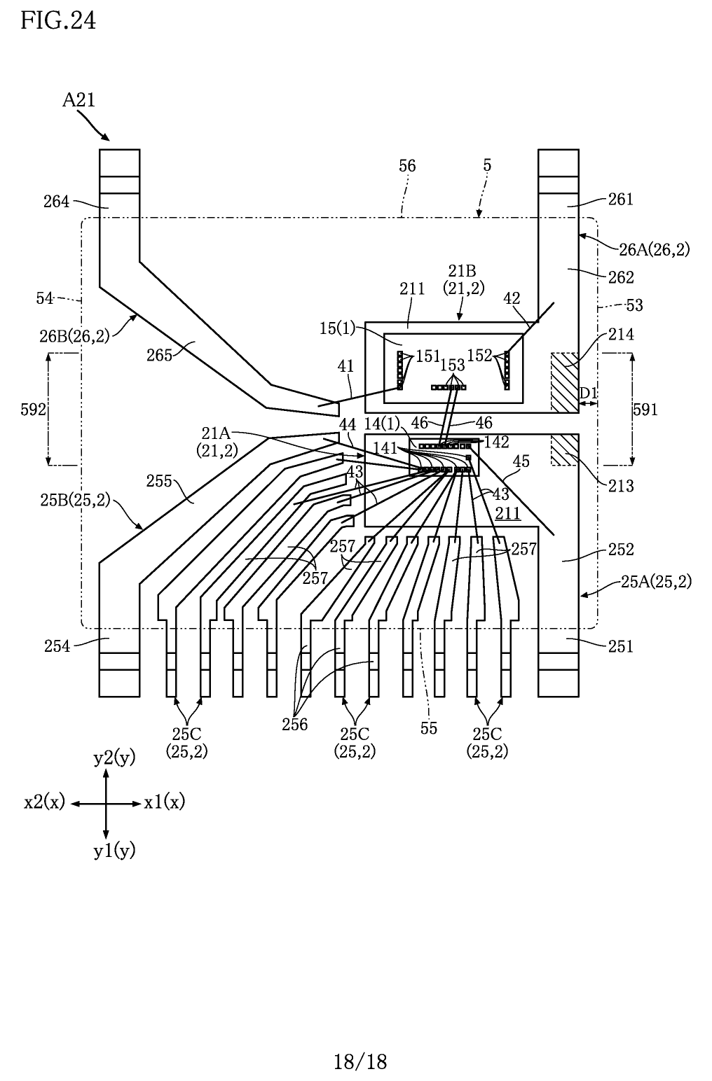

FIG. 24 shows an electronic device according to a first variation of the second embodiment.

FIG. 24 is a plan view of the electronic device A21 according to this variation. For ease of understanding, FIG. 24 depicts the sealing resin 5 as transparent. In FIG. 24, the outline of the sealing resin 5 is indicated by imaginary lines. In FIG. 24, elements that are identical or similar to those of the electronic device A2 of the embodiment described above are denoted by the same reference numerals, and corresponding descriptions are omitted where appropriate.

The electronic device A21 of this variation differs from the electronic device A2 in the arrangements and geometers of the die pad portion 21 (the first die pad 21A and the second die pad 21B), the first lead terminals 25, and the second lead terminals 26.

As shown in FIG. 24, the die pad portion 21 (the first die pad 21A and the second die pad 21B) of the electronic device A21 is positioned closer to the xl side in the first direction x than that of the electronic device A2 described above. The ends of the first die pad 21A and the second die pad 21B on the xl side in the first direction x are the portions of the conductive support member 2 nearest to the first gate mark 591 in the first direction x.

The lead portion 252 of the first-side first terminal 25A extends in the second direction y.

In plan view, the lead portion 252 has a rectangular shape elongated in the second direction y.

The lead portion 252 is connected to the first die pad 21A at the end opposite the terminal portion 251. The lead portion 262 of the first-side second terminal 26A extends in the second direction y. In plan view, the lead portion 262 has a rectangular shape elongated in the second direction y. The lead portion 262 is connected to the second die pad 21B at the end opposite the terminal portion 261.

As shown in FIG. 24, the first die pad 21A includes an inner region 213 that lies inward of the first gate mark 591 in the second direction y, as viewed in the thickness direction z. The second die pad 21B includes an inner region 214 that lies inward of the first gate mark 591 in the second direction y, as viewed in the thickness direction z. The inner regions 213 and 214 are the regions of the conductive support member 2 nearest to the first gate mark 591 in the first direction x. Each of the inner regions 213 and 214 is an example of the "first region" recited in the present disclosure. FIG. 24 shows the inner regions 213 and 214 with hatching.

In the electronic device All of this variation, the first regions (the inner regions 213 and 214 respectively of the first die pad 21A and the second die pad 21B that lie inward of the first gate mark 591 in the second direction y) are positioned relatively close to the first gate mark 591.

During the step of forming the sealing resin 5, if the molten resin flows rapidly through the gate corresponding to the first gate mark 591, the resin may entrap air as it fills the cavity. In the present variation, the inner regions 213 and 214 respectively of the first die pad 21A and the second die pad 21B that lie inward of the first gate mark 591 in the second direction y (the first regions) are positioned relatively close to the first gate mark 591 as described above. Thus, the molten resin strikes the inner regions 213 and 214 (the first regions), thereby slowing its flow and thus reducing the risk of air entrapment. Consequently, pinholes (voids) due to air entrapment are reduced, thereby preventing incomplete filling in the sealing resin 5. Although the molten resin injected through the gate in the step of forming the sealing resin 5 may entrap air, the trapped air breaks down into finer bubbles as the molten resin strikes the first regions (the inner regions 213 and 214 respectively of the first die pad 21A and the second die pad 21B that lie inward of the first gate mark 591 in the second direction y), which is positioned relatively close to the first gate mark 591. Additionally, the electronic device A21 achieves the same operation and effects as the electronic device A2 of the above-described embodiment.

The electronic devices according to the present disclosure are not limited to the embodiments described above. Various modifications in design may be made freely in the specific structure of each part of the electronic device according to the present disclosure.

The present disclosure embodiments described in the following clauses.

### Clause 1.

An electronic device comprising:

a conductive support member; at least one electronic element disposed on a first side in a thickness direction of the conductive support member; and a sealing resin that covers the at least one electronic element and a portion of the conductive support member, wherein the sealing resin includes a first resin side surface facing a first side in a first direction perpendicular to the thickness direction, the first resin side surface includes a first gate mark having a rougher surface than another region of the first resin side surface, the conductive support member includes a first region that is nearest to the first gate mark in the first direction, the first region being positioned inward of the first gate mark in a second direction perpendicular to the thickness direction and the first direction, as viewed in the thickness direction, and a first dimension represents a length of the first gate mark in the thickness direction, a first distance represents a distance between the first gate mark and the first region in the first direction, and a ratio of the first distance to the first dimension is greater than 0% and less than or equal to 500%.

### Clause 2.

The electronic device according to Clause 1, wherein the first distance is greater than 0 mm and less than or equal to 2.4 mm.

### Clause 3.

The electronic device according to Clause 2, wherein a second dimension represents a length of the first gate mark in the second direction, and a product of the second dimension and the first distance ranges from 0.21 mm2 to 5.0 mm2.

### Clause 4.

The electronic device according to any one of Clauses 1 to 3, wherein as viewed in the first direction, the first region overlaps with the first gate mark.

### Clause 5.

The electronic device according to Clause 4, wherein as viewed in the first direction, a ratio of an area where the first region overlaps with the first gate mark to an area of the first gate mark is greater than 0% and less than or equal to 50%.

### Clause 6.

The electronic device according to any one of Clauses 1 to 5, wherein a second dimension represents a length of the first gate mark in the second direction, a third dimension represents a length of the first region in the second direction, and a ratio of the third dimension to the second dimension ranges from 50% to 100%.

### Clause 7.

The electronic device according to Clause 1 or 2, wherein a second dimension represents a length of the first gate mark in the second direction, and a ratio of the first distance to the second dimension is greater than 0% and less than or equal to 50%.

### Clause 8.

The electronic device according to any one of Clauses 1 to 7, wherein the sealing resin includes a resin obverse surface facing the first side in the thickness direction, and a resin reverse surface facing a second side in the thickness direction, and a fourth dimension represents a dimension between the resin obverse surface and the resin reverse surface in the thickness direction, and a ratio of the first distance to the fourth dimension is greater than 0% and less than or equal to 70%.

### Clause 9.

The electronic device according to any one of Clauses 1 to 8, wherein the conductive support member includes a die pad portion, a plurality of first lead terminals, and a plurality of second lead terminals, the sealing resin includes a second resin side surface facing a second side in the first direction, a third resin side surface facing a first side in the second direction, and a fourth resin side surface facing a second side in the second direction, the plurality of first lead terminals each protrude from the third resin side surface toward the first side in the second direction, the plurality of second lead terminals each protrude from the fourth resin side surface toward the second side in the second direction, and the at least one electronic element is mounted on the die pad portion.

### Clause 10.

The electronic device according to Clause 9, wherein the die pad portion includes a first die pad positioned on the first side in the second direction, and a second die pad positioned on the second side in the second direction and spaced apart from the first die pad in the second direction, and the at least one electronic element includes a first electronic element mounted on the first die pad, and a second electronic element mounted on the second die pad.

### Clause 11.

The electronic device according to Clause 10, wherein the plurality of first lead terminals are arranged along the first direction with spacing and include a first-side first terminal that is located outmost on the first side in the first direction, the plurality of second lead terminals are arranged along the first direction with spacing and include a first-side second terminal that is located outmost on the first side in the first direction, and the first region is included in at least one of the first-side first terminal and the first-side second terminal.

### Clause 12.

The electronic device according to Clause 11, wherein an inter-terminal gap is provided between the first-side first terminal and the first-side second terminal in the second direction, an inter-pad gap is provided between the first die pad and the second die pad in the second direction, and the inter-terminal gap overlaps with the inter-pad gap as viewed in the first direction.

### Clause 13.

The electronic device according to Clause 10, wherein the first region is included in the first die pad and the second die pad.

### Clause 14.

An electronic device comprising: a conductive support member; at least one electronic element disposed on a first side in a thickness direction of the conductive support member; and a sealing resin that covers the at least one electronic element and a portion of the conductive support member, wherein the sealing resin includes a first resin side surface facing a first side in a first direction perpendicular to the thickness direction, a second resin side surface facing a second side in the first direction, a third resin side surface facing a first side in a second direction perpendicular to the thickness direction and the first direction, and a fourth resin side surface facing a second side in the second direction, the first resin side surface includes a first gate mark having a rougher surface than another region of the first resin side surface, the conductive support member includes a die pad portion, and a plurality of first lead terminals, the plurality of first lead terminals each protrude from the third resin side surface toward the first side in the second direction, the at least one electronic element is mounted on the die pad portion, the plurality of first lead terminals are arranged along the first direction with spacing and include a first-side first terminal that is located outmost on the first side in the first direction, the first-side first terminal includes a first lead portion, a first pad portion, and a first extending portion, the first lead portion is positioned on the first side in the first direction with respect to the die pad portion and extends in the second direction, the first pad portion is connected to an end of the first lead portion that is on the second side in the second direction and extends toward the second side in the first direction, the first extending portion is connected to the end of the first lead portion that is on the second side in the second direction and extends toward the second side in the second direction, and as viewed in the thickness direction, the first extending portion includes a region that is positioned inward of the first gate mark in the second direction.

### Clause 15.

The electronic device according to Clause 14, wherein the first extending portion includes a region positioned on the first side in the first direction with respect to the first lead portion. Clause 16.

The electronic device according to Clause 14 or 15, wherein the conductive support surface toward the second side in the second direction, the plurality of second lead terminals are arranged along the first direction with spacing and include a first-side second terminal that is located outmost on the first side in the first direction.

Member includes a plurality of second lead terminals each protruding from the fourth resin side the first-side second terminal includes a second lead portion, a second pad portion, and a second extending portion, the second lead portion is positioned on the first side in the first direction with respect to the die pad portion and extends in the second direction, the second pad portion is connected to an end of the second lead portion that is on the first side in the second direction and extends toward the second side in the first direction, the second extending portion is connected to the end of the second lead portion that is on the first side in the second direction and extends toward the first side in the second direction, and as viewed in the thickness direction, the second extending portion includes a region that is positioned inward of the first gate mark in the second direction, the second extending portion being spaced apart from the first extending portion toward the second side in the second direction.

### Clause 17.

The electronic device according to Clause 16, wherein the second extending portion includes a region positioned on the first side in the first direction with respect to the second lead portion.

### REFERENCE NUMERALS

A1, All, A2, A21: electronic device 1: electronic element 11: first semiconductor element (first electronic element) 111: electrode 12: insulating element 121: first electrode 122: second electrode 13: second semiconductor element (second electronic element) 131: electrode 14: first electronic element 141, 142: electrode 15: second electronic element 151, 152, 153: electrode 2: conductive support member 1: semiconductor element 21: die pad portion 21A: first die pad 21B: second die pad 211: mounting surface 212: through-hole 213 and 214: inner region (first region) 22: first lead terminal 22A: first-side first terminal 22B: second-side first terminal 22C: intermediate first terminal 221: first lead portion 222: first pad portion 223: first extending portion 224, 226: lead portion 225, 227: pad portion 23: second lead terminal 23A: first-side second terminal 23B: second-side second terminal 23C: intermediate second terminal 231: second lead portion 232: second pad portion 233: second extending portion 234, 236: lead portion 235, 237: pad portion 25: first lead terminal 25A: first-side first terminal 25B: second-side first terminal 25C: intermediate first terminal 251, 254, 256: terminal portion 252, 255, 257: lead portion 26: second lead terminal 26A: first-side second terminal 26B: second-side second terminal 261, 264: terminal portion 262, 265: lead portion 262a: inner region (first region) 31 to 34: wire 41 to 46: wire 5: sealing resin 51: resin obverse surface 52: resin reverse surface 53: first resin side surface 531: first upper section 532: first lower section 533: first intermediate section 54: second resin side surface 541: second upper section 542: second lower section 543: second intermediate section 55: third resin side surface 551: third upper section 552: third lower section 553: third intermediate section 56: fourth resin side surface 561: fourth upper section 562: fourth lower section 563: fourth intermediate section 591: first gate mark 592: second second gate D1: first distance L1: first dimension L2: second dimension L3: third dimension L4: fourth dimension S1, S2: area OP: operational amplifier R1 to R5: resistive element T1, T2: terminal gate mark 81: lead frame 81A: obverse surface 81B: reverse surface 811: outer frame 812A: first die pad 812B: second die pad 813: first lead 814: second lead 815: support lead 816: dam bar 817: extending portion 891: first gate 892:

1. An electronic device comprising:a conductive support member;at least one electronic element disposed on a first side in a thickness direction of the conductive support member; anda sealing resin that covers the at least one electronic element and a portion of the conductive support member,wherein the sealing resin includes a first resin side surface facing a first side in a first
direction perpendicular to the thickness direction,the first resin side surface includes a first gate mark having a rougher surface than another region of the first resin side surface,the conductive support member includes a first region that is nearest to the first gate mark in the first direction, the first region being positioned inward of the first gate mark in a second
direction perpendicular to the thickness direction and the first direction, as viewed in the thickness direction, anda first dimension represents a length of the first gate mark in the thickness direction, a first distance represents a distance between the first gate mark and the first region in the first direction, and a ratio of the first distance to the first dimension is greater than 0% and less than or equal to
500%.

2. The electronic device according to claim 1, wherein the first distance is greater than 0 mm and less than or equal to 2.4 mm.

3. The electronic device according to claim 2, wherein a second dimension represents a length of the first gate mark in the second direction, and a product of the second dimension and the first distance ranges from 0.21 mm²5to .0 mm².

4. The electronic device according to claim 1, wherein as viewed in the first direction, the first
region overlaps with the first gate mark.

5. The electronic device according to claim 4, wherein as viewed in the first direction, a ratio of an area where the first region overlaps with the first gate mark to an area of the first gate mark is greater than 0% and less than or equal to 50%.

6. The electronic device according to claim 1, wherein a second dimension represents a length of the first gate mark in the second direction, a third dimension represents a length of the first region in the second direction, and a ratio of the third dimension to the second dimension ranges from 50% to 100%.

7. The electronic device according to claim 1, wherein a second dimension represents a length of the first gate mark in the second direction, and a ratio of the first distance to the second dimension is greater than 0% and less than or equal to 50%.

8. The electronic device according to claim 1, wherein the sealing resin includes a resin obverse surface facing the first side in the thickness direction, and a resin reverse surface facing a second side in the thickness direction, anda fourth dimension represents a dimension between the resin obverse surface and the resin reverse surface in the thickness direction, and a ratio of the first distance to the fourth dimension
is greater than 0% and less than or equal to 70%.

9. The electronic device according to claim 1, wherein the conductive support member includes a die pad portion, a plurality of first lead terminals, and a plurality of second lead terminals,the sealing resin includes a second resin side surface facing a second side in the first
direction, a third resin side surface facing a first side in the second direction, and a fourth resin side surface facing a second side in the second direction,the plurality of first lead terminals each protrude from the third resin side surface to ward the first side in the second direction,the plurality of second lead terminals each protrude from the fourth resin side surface
toward the second side in the second direction, andthe at least one electronic element is mounted on the die pad portion.

10. The electronic device according to claim 9, wherein the die pad portion includes a first die pad positioned on the first side in the second direction, and a second die pad positioned on the
second side in the second direction and spaced apart from the first die pad in the second direction,
and the at least one electronic element includes a first electronic element mounted on the first die pad, and a second electronic element mounted on the second die pad.

11. The electronic device according to claim 10, wherein the plurality of first lead terminals are
arranged along the first direction with spacing and include a first-side first terminal that is located outmost on the first side in the first direction,the plurality of second lead terminals are arranged along the first direction with spacing and include a first-side second terminal that is located outmost on the first side in the first direction,
and the first region is included in at least one of the first-side first terminal and the first-side second terminal.

12. The electronic device according to claim 11, wherein an inter-terminal gap is provided
between the first-side first terminal and the first-side second terminal in the second direction, an inter-pad gap is provided between the first die pad and the second die pad in the second direction,
and the inter-terminal gap overlaps with the inter-pad gap as viewed in the first direction.

13. The electronic device according to claim 10, wherein the first region is included in the first
die pad and the second die pad.

14. An electronic device comprising:a conductive support member;at least one electronic element disposed on a first side in a thickness direction of the
conductive support member; anda sealing resin that covers the at least one electronic element and a portion of the conductive support member,wherein the sealing resin includes a first resin side surface facing a first side in a first direction perpendicular to the thickness direction, a second resin side surface facing a second side
in the first direction, a third resin side surface facing a first side in a second direction perpendicular to the thickness direction and the first direction, and a fourth resin side surface facing a second side in the second direction,the first resin side surface includes a first gate mark having a rougher surface than another region of the first resin side surface,the conductive support member includes a die pad portion, and a plurality of first lead terminals,the plurality of first lead terminals each protrude from the third resin side surface toward the first side in the second direction,the at least one electronic element is mounted on the die pad portion,the plurality of first lead terminals are arranged along the first direction with spacing and
include a first-side first terminal that is located outmost on the first side in the first direction,the first-side first terminal includes a first lead portion, a first pad portion, and a first extending portion,the first lead portion is positioned on the first side in the first direction with respect to the
die pad portion and extends in the second direction,the first pad portion is connected to an end of the first lead portion that is on the second side in the second direction and extends toward the second side in the first direction,the first extending portion is connected to the end of the first lead portion that is on the second side in the second direction and extends toward the second side in the second direction, and as viewed in the thickness direction, the first extending portion includes a region that is positioned inward of the first gate mark in the second direction.

15. The electronic device according to claim 14, wherein the first extending portion includes a
region positioned on the first side in the first direction with respect to the first lead portion.

16. The electronic device according to claim 14, wherein the conductive support member includes a plurality of second lead terminals each protruding from the fourth resin side surface toward the second side in the second direction,the plurality of second lead terminals are arranged along the first direction with spacing and include a first-side second terminal that is located outmost on the first side in the first direction.the first-side second terminal includes a second lead portion, a second pad portion, and a second extending portion,the second lead portion is positioned on the first side in the first direction with respect to
the die pad portion and extends in the second direction,the second pad portion is connected to an end of the second lead portion that is on the first side in the second direction and extends toward the second side in the first direction,the second extending portion is connected to the end of the second lead portion that is on the first side in the second direction and extends toward the first side in the second direction, and as viewed in the thickness direction, the second extending portion includes a region that is positioned inward of the first gate mark in the second direction, the second extending portion being spaced apart from the first extending portion toward the second side in the second direction.

17. The electronic device according to claim 16, wherein the second extending portion includes
a region positioned on the first side in the first direction with respect to the second lead portion.
